(19) United States
(12) Patent Application Publication
(10) Pub. No.: US 2009/0103401 A1
(43) Pub. Date: Apr. 23, 2009

(54) MAGNETIC RECORDING MEDIUM, PRODUCTION METHOD FOR THE SAME, AND RECORDING/REPRODUCING METHOD FOR MAGNETIC MEDIUM

(75) Inventor: Motoyoshi Murakami, Osaka (JP)

Correspondence Address: WENDEROTH, LIND & PONACK L.L.P., 1030 15th Street, N.W., Suite 400 East, Washington, DC, 20005-1503, US

(73) Assignee: MATSUSHITA ELECTRIC INDUSTRIAL CO., LTD., Osaka (JP)

(21) Appl. No.: 11/915,278

(22) PCT Filed: May 16, 2006
(86) PCT No.: PCT/JP2006/309701

§ 371 Date: Oct. 3, 2008

(30) Foreign Application Priority Data
May 25, 2005 (JP) 2005-152093

(51) Int. Cl. G11B 11/00; G11B 5/82; C23C 14/34

(52) U.S. Cl. 369/13.24; 360/135; 204/192.1; 427/127; 977/778; G9B/5.293; G9B/11

(57) ABSTRACT

A magnetic recording medium with excellent signal characteristics is provided in which the stability of recorded information is ensured even when recording is performed in high density or even when magnetic recording and reproduction are performed while the temperature of a recording film is increased by irradiation with light. The present invention provides a magneto-optical recording medium comprising at least a memory layer on a disk substrate, in which the memory layer is separated into magnetic grains to form magnetically isolated recorded domains, or in which a fine structure is formed by an aggregate of mutually isolated magnetic grains in the memory layer, and the memory layer has a large specific resistance. A production method thereof is also provided.

### TECHNICAL FIELD

The present invention relates to a rewritable magnetic recording medium or a magnetic recording medium on which signals are recorded and reproduced while the temperature of the magnetic recording medium is being raised through light irradiation, and particularly a magnetic recording medium which can achieve high-density recording, and a production method and a recording and reproducing method for such a magnetic recording medium.

### BACKGROUND ART

Optical recording media, such as magneto-optical magnetic recording media and phase-change recording media, are portable recording media capable of large-capacity and high-density recording. A recent advancement in multimedia technology is rapidly increasing a demand for the optical recording media to record large computer files and moving images.

The optical recording medium typically comprises a transparent disk-shaped substrate made of plastic or the like, and multiple films including a recording layer which are provided on the substrate. The optical recording medium is irradiated with laser light while being subjected to focus servo, and tracking servo using guide grooves or prepits so as to record or erase information onto or from the optical recording medium or reproduce a signal from the optical recording medium using reflected laser light.

Conventionally, the magneto-optical recording medium predominantly employs so-called optical modulation recording, in which erasure is performed by applying a stationary magnetic field before recording is performed by applying a stationary magnetic field in the opposite direction. In recent years, attention has been paid to magnetic field modulation recording, in which a magnetic field is modulated according to a recording pattern while the recording medium is being irradiated with laser light, recording can be performed by a single rotation (direct overwrite), and recording can be correctly performed even in high recording density. Attention has also been paid to phase-change recording media, which enable direct overwrite by optical modulation recording and can be reproduced using the same optical system as that for CDs or DVDs.

The maximum recording density of the optical recording medium depends on its optical diffraction limit (up to λ/2NA, where NA is the numeric aperture of an objective lens), which is determined by the wavelength (λ) of laser light from a light source. Recently, a system which uses two objective lenses and thereby has an NA of 0.8 or more has been proposed and actively developed. The recording film is irradiated with laser light for recording and reproduction, conventionally through the substrate. Aberration which occurs due to, for example, skew of the substrate when light is passed through the substrate increases with an increase in NA. Therefore, the substrate is required to be thinner.

Magnetic recording media have achieved higher recording densities than those of optical recording media by improvements in the media and GMR (giant magneto resistive) heads or the like which have come into practical use. To further increase the recording density of magnetic recording media, improvements in the technique of increasing the density of the recording film and the technique of interfacing a disk and a head are essentially required.

For magneto-optical recording media, a technique of apparently increasing a reproduced signal by displacement of a magnetic domain wall has been proposed (see, for example, Patent Document 1). However, this technique has a problem with high-density recording of the recording film.

In the case of magnetic recording, smaller and denser recorded domains have raised a problem with the thermal stability of recorded magnetic domains. Therefore, the stability of the recorded magnetic domain and reliability required as an information storage medium need to be secured.

Patent Document 1: Japanese Unexamined Patent Publication No. H6-290496

### DISCLOSURE OF INVENTION

### Technical Problem

However, when the density of the conventional magnetic recording medium described above is increased, the recorded magnetic domain has a problem with its thermal stability, so that its magnetic anisotropy needs to be increased.

FePt magnetic materials have a high level of magnetic anisotropy, but requires an annealing treatment at high temperature in order to attain uniform crystal orientation.

Rare earth metal-transition metal-based materials are amorphous materials. Therefore, the magnetic domain wall displacement causes a magnetic domain of a small recording mark to become unstable and vanish or disappear.

In all of the above-described methods, it is difficult to secure the stability of high-density recording employing small recording marks and a sufficient level of long-term reliability required as an information storage medium.

An object of the present invention is to provide a magnetic recording medium which secures the stability of recorded information and excellent signal characteristics even when recording is performed in high density.

Another object of the present invention is to provide a magnetic recording medium which has an increased level of stability of small recording marks and excellent signal characteristics even when magnetic recording and reproduction are performed while the temperature of the recording film is raised by light irradiation.

### Technical Solution

A magnetic recording medium according to the present invention comprises a magnetic recording film including a memory layer made of an amorphous material having magnetic anisotropy at least in an out-of-plane direction on a disk substrate, wherein (1) at least the memory layer is an aggregate of mutually magnetically isolated magnetic grains, or (2) at least the memory layer is an aggregate of magnetic grains having a density or a composition periodically varying in an in-plane direction.

In the magnetic recording medium, the magnetic grain may have a width of 2 nm to 50 nm as a structural unit.

The memory layer preferably has a composition or a density periodically varying in the in-plane direction, depending on the width of the magnetic grain.

Further, the magnetic grains are preferably mutually magnetically isolated in the memory layer.

Also, preferably, any one or two or more of the following features are provided: (i) a modulation cycle in the in-plane direction of the composition or density is smaller than a film thickness of the memory layer; (ii) the memory layer includes magnetic grains forming recorded magnetic domains and border regions between the magnetic grains; (iii) the border region has a coercive force or a magnetic domain wall energy density smaller than that of the magnetic grain; (iv) a width in the in-plane direction of the border region is smaller than the film thickness of the memory layer; (v) a resistivity in the in-plane direction of the memory layer is 500 μΩcm or more; (vi) the magnetic grains in the memory layer are column-shaped structures which are mutually magnetically isolated; (vii) the memory layer is separated into the mutually magnetically isolated magnetic grains in first cycles which are the same as changes of a surface shape of an underlying layer or in second cycles, each of which is an integral multiple of the first cycle; (viii) in the border regions between the magnetic grains, the memory layer contains at least one element selected from the group consisting of hydrogen and inert gaseous elements, and except for the element, the memory layer has a uniform composition; (ix) the inert gaseous element is at least one selected from He, Ne, Ar, Kr, and Xe; (x) the memory layer contains a rare earth metal; (xi) the rare earth metal is at least one of Tb, Gd, and Dy; (xii) the rare earth metal is contained in the memory layer in an amount of 15 at % to 28 at %; (xiii) the memory layer has a film thickness of 10 nm to 400 nm; (xiv) the magnetic recording film includes a readout layer magnetically coupled with the memory layer; (xv) the memory layer and the readout layer have different magnetic domain wall energy densities; (xvi) the magnetic recording film further includes an intermediate layer, and the intermediate layer has a larger magnetic domain wall energy density than that of the readout layer; (xvii) the intermediate layer has a larger magnetic anisotropy in an out-of-plane direction than that of the readout layer at room temperature; (xviii) the readout layer has magnetic domain wall energy differing between in an in-plane direction and in an out-of-plane direction; (xix) the readout layer has a smaller magnetic domain wall coercive force than those of the memory layer and the intermediate layer; (xx) a magnetic domain wall width in the in-plane direction of the intermediate layer is smaller than a magnetic domain wall width of the readout layer and a magnetic domain wall width in the out-of-plane direction of the intermediate layer; (xxi) a magnetic domain wall width in a depth direction of the intermediate layer is smaller than a film thickness thereof; (xxii) the disk substrate has concaves and convexes in a surface thereof; (xxiii) concaves and convexes are formed in a surface which the memory layer contacts.

The present invention also provides a method for producing a magnetic recording medium comprising a magnetic recording film including a memory layer made of an amorphous material having magnetic anisotropy at least in an out-of-plane direction on a disk substrate, wherein (1) the memory layer is formed on a layer having a surface roughness of 0.5 nm or more, (2) the memory layer is formed in a vacuum atmosphere by controlling conditions for formation of the layer so that the energy density of an element included in the memory layer is 1 A/mm² or less, (3) the memory layer is formed in a vacuum atmosphere by controlling conditions for formation of the layer so that a voltage applied to an element included in the memory layer is 300 W or less, or (4) the memory layer is formed at a pressure of 2 Pa or more.

The present invention also provides a recording and reproducing method for the magnetic recording medium above, wherein (1) an information signal is recorded to or reproduced from the magnetic recording medium while increasing the temperature of the memory layer by irradiating the magnetic recording medium with a laser spot, or (2) an information signal is recorded to or reproduced from the magnetic recording medium using a magnetic head.

### ADVANTAGEOUS EFFECTS

According to the present invention, a small recorded magnetic domain can be stably recorded, and recording density can be significantly improved without a deterioration in reproduced signal amplitude. Thus, a magnetic recording medium can be provided in which, even when recording is performed in high density, the stability of recorded information is ensured, and excellent signal characteristics are obtained.

Also, in the recording medium on which magnetic recording and reproduction are performed while the temperature of the recording film is increased by irradiation with light, servo characteristics can be stabilized, thereby improving reliability, leading to higher productivity of the disk and a significant reduction in cost.

Further, it is possible to provide a magnetic recording medium in which, even when rewriting is repeatedly performed in high density, stable recording and reproduction characteristics are obtained, and excellent signal characteristics are obtained, a production method thereof, and a recording and reproducing method thereof.

### BEST MODE FOR CARRYING OUT THE INVENTION

Hereinafter, the present invention will be described, by way of example, in more detail. The present invention is not limited to embodiments described below, as long as the scope of the invention is not exceeded.

A magnetic recording medium according to the present invention includes, on a disk substrate, a memory layer made of an amorphous material having magnetic anisotropy in at least a direction perpendicular to a film surface thereof (hereinafter referred to as an out-of-plane direction). The memory layer is an aggregate of magnetic grains which are magnetically isolated from each other. In other words, the memory layer contains magnetic grains, each of which independently undergoes magnetization reversal, or the magnetic grains are separated structures which are each in the shape of a column. Also, in other words, the memory layer is an aggregate of magnetic grains whose density or composition varies periodically in a direction parallel to the film surface (hereinafter referred to as an in-plane direction), for example. Specifically, as shown in FIG. 12, if the composition of the layer varies, or if the composition is substantially uniform but the density varies, the magnitude of magnetization per unit volume varies, so that the magnetic anisotropy of the memory layer varies in association with the variation of magnetization in the layer.

The magnetic domain wall energy density σw of the memory layer, which is represented by 4(AKu)^{1/2} (A is an exchange stiffness constant), is proportional to the square root of the magnetic anisotropy constant Ku, and therefore, similarly varies in the in-plane direction. Also, coercive force varies depending on the magnetic anisotropy. Thus, a decrease in magnetic domain wall energy particularly a border region (i.e., a magnetic domain wall) between each magnetic grain, may hinder displacement of the magnetic domain wall during formation of a recorded magnetic domain. Therefore, a magnetic domain wall at a border of recorded magnetic domains is immobilized, so that the recorded magnetic domain can be stabilized. Thereby, a small recorded magnetic domain is advantageously formed. As a result, small marks can be recorded, thereby making it possible to achieve high-density recording and reproduction. A change in coercive force at particularly a border region between each magnetic grain is a hindrance at the border of recorded magnetic domains, thereby making it possible to stabilize a mark shape of the recorded magnetic domain.

The changes in the composition or density in the in-plane direction of the memory layer are preferably periodic and correspond to a width of the magnetic grain. For example, the magnetic grain preferably has a width of about 2 to 50 nm, and is preferably smaller than a film thickness of the memory layer itself. Similarly, the border region between each magnetic grain is preferably smaller than the film thickness of the memory layer. Thereby, magnetic domain walls are likely to be formed in the in-plane direction. From another viewpoint, the changes in the composition or density of the memory layer has a cycle that is the same as or an integral multiple of that of changes in a surface shape of an underlying layer. The memory layer preferably has a resistivity of 500 μΩcm or more in the in-plane direction. This is because the resistivity of the memory layer is closely involved with the presence or absence, density, composition and the like of the magnetic grain, and are increased due to changes in those factors.

Note that the changes in the composition or density of the memory layer is affected not only by the presence or absence of the magnetic grain, but also by the presence or absence of a gaseous element in the border region of the magnetic grain. Therefore, the composition is uniform throughout the memory layer, but a gaseous element (e.g., hydrogen, inert gas (He, Ne, Ar, Kr, or Xe), or a combination thereof) is preferably added only to the border region of the magnetic grain. Thereby, magnetic anisotropy changes in the border region of the magnetic grain, so that the magnetic domain wall is likely to be formed, and therefore, the small magnetic domain is stabilized.

### EMBODIMENT 1

FIG. 1 shows a structure of a magnetic recording medium (hereinafter referred to as a magnetic disk) according to Embodiment 1 of the present invention. The magnetic disk 1 comprises a dielectric layer 3, an underlying magnetic layer 4, a magnetic recording film 5 including a memory layer, and a dielectric protective layer 6 for protecting the magnetic recording film 5, which are laminated, one on top of another in the stated order, on a transparent disk substrate 2 made of, for example, crystal glass or a plastic, such as polycarbonate. On the resultant multilayer structure, a lubricating layer 7 is also laminated for protection of the recording film and sliding movement. A texture layer 8 which has been subjected to a texture treatment is provided on a surface of the lubricating layer 7.

The disk substrate 2 has a guide groove formed in a track for recording information. A pit region for servo and a data region for recording information are formed in the recording track. Pits for tracking servo and address detection are formed in the pit region. A track pitch is 0.3 μm.

The underlying magnetic layer 4 is controlled so as to form magnetically isolated film structures in the recording film 5 for recording information, and is exchange-coupled with the recording film 5.

The magnetic disk 1 can be fabricated as follows.

Firstly, the disk substrate 2 is prepared. In the disk substrate 2, a guide groove (i.e., grooves and lands (not shown)) is formed by a pressure imprint method using a stamper having grooves and lands.

Next, a Si target is set in a DC magnetron sputtering apparatus and a disk substrate is fixed to a substrate holder. Thereafter, the chamber is evacuated to a high vacuum of 7*10⁻⁶ Pa or less using a turbomolecular pump. Ar gas and N₂ gas are introduced into the chamber to 0.3 Pa while evacuation is maintained. The dielectric layer 3 made of SiN (film thickness: 50 nm) is formed by reactive sputtering while the substrate is being rotated. Ar gas is introduced into the chamber to 0.5 Pa. The underlying magnetic layer 4 made of GdFeCo (35 nm) is formed by DC magnetron sputtering using targets of Gd, Fe, and Co while the substrate is being rotated. Further, Ar gas is introduced into the chamber to 2.5 Pa. The magnetic recording film 5 made of TbFeCo (100 nm) is formed by DC magnetron sputtering using targets of Tb, Fe, Co, and Cr.

The film composition can be caused to have a desired value by adjusting the ratio of powers applied to the targets.

Here, the composition of the magnetic recording film 5 made of TbFeCo is adjusted by setting the application powers of the targets so that the compensation composition temperature is −50° C. and the Curie temperature is 320° C. The memory layer made of this composition has a coercive force of as large as 15 koe and a high level of magnetic anisotropy in the out-of-plane direction at room temperature. Also, after the underlying magnetic layer 4 is formed, if the underlying recording layer 4 is sputtered in Ar gas of 2 Pa or more, the magnetic recording film 5 having small column-shaped structures (in other words, grain structures) can be formed.

FIG. 2A shows a schematic diagram of a cross-section of the thus-obtained magnetic recording film 5 which was observed by an SEM. As can be seen from FIG. 2A, small column-shaped structures are formed in the magnetic recording film 5, and each small column-shaped structure has magnetically isolated characteristics. Therefore, when an information signal is recorded as a small magnetic domain, a stable recorded magnetic domain can be formed. Also, when a signal is repeatedly recorded and reproduced, excellent recording and reproduction can be performed with a less deterioration in signal characteristics. On the other hand, as shown in FIG. 2B, a uniform and continuous film is formed in a conventional magnetic recording film 5a having no columns. Therefore, a magnetic domain wall is easily displaced.

Note that, apart from the above, a magnetic memory layer made of TbₓFe₈₄₋ₓCo₁₆ (17≦x≦34) (a film corresponding FIG. 2A) was formed in which small column-shaped structures are formed by changing the Tb content, and each column has magnetically isolated characteristics. Also, for comparison, an amorphous memory layer having the same composition (a film corresponding to FIG. 2B) was formed. Changes in coercive force in these memory layers were measured. The results are shown in FIG. 13. As can be seen from FIG. 13, the film having small column-shaped structures (solid line) has larger coercive force than that of the comparative film (dotted line).

Magnetic memory layers made of Tb₂₈Fe₅₆Co₁₆ which correspond to FIGS. 2A and 2B were formed and their temperature dependence of coercive force was measured. The results are shown in FIG. 14. As can be seen from FIG. 14, the film having small column-shaped structures (solid line) has larger coercive force than that of the comparative film (dotted line). Thereafter, the protective layer 6 (5 nm) made of diamond-like carbon (DLC) is formed on the magnetic recording film 5 by reactive RF sputtering using a C target in an atmosphere of a mixture of Ar and CH₄. Perfluoropolyether (hereinafter referred to as PFPE) is applied onto the protective layer 6 to form the lubricating layer 7 (5 nm).

Next, a surface of the lubricating layer 7 is subjected to a texture treatment by etching so that the surface roughness Ra is 0.7 nm or more, thereby providing the texture layer 8. Thereby, large protrusions are removed, so that small concaves and convexes can be formed, which prevent adhesion of a magnetic head. Therefore, levitation of the magnetic head can be easily controlled.

The recording film of the magnetic disk is irradiated with focused laser light (i.e., a laser spot) so as to record a signal which is modulated by the magnetic head, depending on an information signal. During signal reproduction, a laser spot having only a single plane of polarization is emitted by an optical head, and reflected light or transmitted light from a recorded magnetic domain is detected to reproduce a signal, thereby making it possible to record and reproduce recording marks which are recorded in high density.

Alternatively, a recording and reproducing apparatus employing the magnetic disk may be used. In this case, the disk is rotated, and modulated by a magnetic head using a recording signal which has been modulated with an information signal, while the disk is being irradiated with laser light by an optical head. During signal reproduction, a signal is reproduced by detecting a magnetic flux from a recorded magnetic domain using the magnetic head.

The magnetic recording medium of the present invention can overcome the following drawbacks of conventional magnetic recording media: (1) particularly when an attempt is made to record a small mark, a recorded magnetic domain is expanded or extinguished by displacement of a magnetic domain wall, so that stable recording cannot be achieved; and (2) this phenomenon particularly becomes significant when recording density is high, and a problem with thermal stability deteriorates reliability after long-time storage.

Specifically, in the magnetic recording medium of the present invention, a memory layer is formed on a disk substrate, and the memory layer has small film structures (i.e., isolated magnetic grains). Therefore, even when recording is performed in high density, marks can be stabilized. Also, even when there is a change in ambient temperature or the like, the small structures of the recording film can be stabilized. Therefore, a magnetic recording medium having excellent stability against temperature changes and excellent signal characteristics can be achieved.

### EMBODIMENT 2

FIG. 3 shows a structure of a magnetic recording medium (hereinafter referred to as a magnetic disk) according to this embodiment. The magnetic disk 10 comprises a dielectric layer 12, a magnetic recording film including a memory layer 13, an intermediate layer 14 and a readout layer 15, and a dielectric layer 16 for protecting the magnetic recording film, which are laminated, one on top of another in the stated order, on a polished disk substrate 11 made of an Al alloy. On the resultant multilayer structure, a lubricating layer 17 for protection of the magnetic recording film and sliding movement of a head is provided.

The disk substrate 12 has a guide groove formed in a track for recording information. The guide groove includes grooves 18a and 18b and lands 19a and 19b. A pit region for servo and a data region for recording information are formed in the recording track. Pits for tracking servo and address detection are formed in the pit region. A track pitch is 0.3 μm.

The magnetic recording film includes the memory layer 13 for holding information, the readout layer 15 for detecting information by displacement of a magnetic domain wall, and the intermediate layer (or, an intermediate isolating layer) 14 for controlling exchange-coupling between the readout layer and the memory layer.

This magnetic recording medium is applicable to DWDD, which sequentially displaces domain walls immediately when a laser beam reaches the domain walls by using a temperature gradient produced by the laser beam and detects displacement of the domain walls using an optical head, thereby improving the sensitivity of signal detection during reproduction and enabling magnetically induced super-resolution reproduction.

The magnetic recording film of the magnetic recording medium is one of the recording films which are applicable to DWDD (Domain Wall Displacement Detection), which is one of the technologies of increasing the amplitude and amount of a reproduced signal by utilizing displacement of a domain wall. As disclosed in, for example, Patent Document 1, the memory layer is formed of a magnetic film having a large interfacial saturation coercive force, the readout layer in which domain walls are displaced is formed of a magnetic film having a small interfacial saturation coercive force, and the intermediate layer for switching is formed of a magnetic film having a relatively low Curie temperature. Therefore, the magnetic recording film is not limited to this film structure, as long as the magnetic recording film is composed of any magnetic film that is applicable to DWDD.

The basic principle of reproduction with DWDD will be described with reference to FIG. 11.

FIG. 11A is a diagram showing a cross-section of a recording film of a magnetic disk while the magnetic disk is being rotated. The recording film has a triple-layer structure including a readout layer 113, an intermediate layer 114, and a memory layer 115, which are formed on a disk substrate and a dielectric layer (not shown). Although not shown, a dielectric layer, a protective layer, and/or a lubricating sliding layer are also formed.

The readout layer 113 is formed of a magnetic film material having a small domain wall coercive force. The intermediate layer 114 is formed of a magnetic film having a low Curie temperature. The memory layer 115 is formed of a magnetic film which can hold a recorded magnetic domain even with a small domain diameter. Here, the readout layer of the magnetic recording medium has a magnetic domain structure including an unclosed domain wall which is formed by forming a guard band or the like between recording tracks.

As shown in the figure, an information signal is formed as a recorded magnetic domain which has been thermomagnetically recorded in the memory layer. In the recording film at room temperature without irradiation with a laser spot, the memory layer, the intermediate layer, and the readout layer are strongly exchange-coupled to each other. In this state, a recorded magnetic domain of the memory layer is transferred and formed, as it is in the memory layer, to and in the readout layer.

FIG. 11B shows a relationship between positions χ corresponding to the cross-sectional view of FIG. 11A and temperatures T of the recording film. During reproduction of a recording signal, the disk is rotated and is irradiated with a reproduction beam spot of laser light along a track as shown in the figure. In this case, the recording film has a temperature distribution as shown in FIG. 11B. The temperature distribution includes a temperature region Ts in which the temperature of the intermediate layer (also referred to as an intermediate isolating layer or a switching layer) reaches the Curie temperature Tc or more. In the temperature region Ts, the exchange-coupling between the readout layer and the recording layer is decoupled.

When a reproduction beam is applied, domain wall energy densities σ at positions χ in a disk rotating direction corresponding to the positions of FIGS. 11A and 11B will have energy density gradients as indicated by dependency on the domain wall energy density σ shown in FIG. 11C. As a result, driving forces F which drive a domain wall act on a domain wall at positions χ in each layer as shown in FIG. 11D.

The force F acting on the recording film acts to displace a domain wall toward a smaller domain wall energy density σ as shown in the figure. The readout layer has a small domain wall coercive force and a high domain wall mobility. Therefore, assuming that the readout layer is provided alone, if the readout layer has an unclosed domain wall, the domain wall is easily displaced by the force F. As a result, the domain wall in the readout layer is instantaneously displaced toward a region having a higher temperature and a smaller domain wall energy density as indicated by arrows. When a domain wall passes through the reproduction beam spot, the readout layer will have the same direction of magnetization over a wide region of the light spot.

As a result, a reproduced magnetic domain will always have a constant maximum amplitude irrespective of the size of a recorded magnetic domain. Even when a signal is reproduced using an optical head or a magnetic head, such as a GMR head, then if a transferred magnetic domain in the readout layer is expanded by a temperature gradient caused by a light beam or the like, the reproduced signal will always have an amount corresponding to the constant maximum amplitude.

The magnetic disk 10 can be fabricated as follows.

First, the disk substrate 11 is prepared. The grooves 18a and 18b and the lands 19a and 19b are formed in the disk substrate 11 by a heat imprint method using a stamper having grooves and lands.

Next, pits are formed in a surface of the disk substrate 11 using a photopolymer. Portions other than the pits are etched by an ion gun through a mask to cause the pit to have a surface roughness Ra of 0.5 nm or more. Thereby, pits having different surface roughnesses Ra can be formed. In this case, pits having a small surface roughness can be used for servo. Alternatively, in the case of formation of magnetic pits, the pits are recorded by magnetic contact duplication or using a servo writer or the like, after a recording film is formed on the disk substrate.

Next, an AlTi target is set in a DC magnetron sputtering apparatus, and the disk substrate is fixed to a substrate holder. Thereafter, the chamber is evacuated to a high vacuum of 7*10⁻⁶ Pa or less using a turbomolecular pump. Ar gas and N₂ gas are introduced into the chamber to 0.3 Pa while the chamber is evacuated. The dielectric layer 12 made of AlTiN (50 nm) is formed by reactive sputtering while the substrate is being rotated. When the dielectric layer 12 is thus formed on the disk substrate 11 having the above-described concaves and convexes or the like, the pits on the surface of the disk substrate 11 are also formed in a surface of the dielectric layer 12.

Ar gas is introduced into the chamber to 2.5 Pa. Thereafter, while the substrate is being rotated, targets of Tb, Fe, Co, of Cr are used to form the memory layer 13 of TbFeCo (100 nm) by DC magnetron sputtering. Further, the same targets are used to form the intermediate layer 14 of TbFeCoCr (20 nm) by DC magnetron sputtering. Further, targets of Gd, Fe, and Co are used, Ar gas is introduced into the chamber to 0.5 Pa, and the readout layer 15 of GdFeCo (35 nm) is formed by DC magnetron sputtering.

Here, the film compositions can be caused to have desired values by adjusting power ratio applied to the targets.

Here, the composition of the memory layer 13 made of TbFeCo is adjusted by setting power applied to each target so that the compensation composition temperature is 70° C. and the Curie temperature is 300° C. The resultant composition provides a memory layer which has a coercive force of as large as 19 koe at room temperature and a high level of magnetic anisotropy in the out-of-plane direction. Also, by successively laminating a dielectric layer and a memory layer on a disk substrate whose surface has small concaves and convexes (surface roughness Ra: 0.5 nm or more), a memory layer can be formed which is an aggregate of isolated magnetic grains. Thereby, when an information signal is recorded into a small magnetic domain, the recorded magnetic domain can be stabilized. Also, even when a signal is repeatedly recorded and reproduced, recording and reproduction can be excellently performed with a less deterioration in signal characteristics.

Thereafter, the dielectric layer 16 made of amorphous carbon (αC) (7 nm) is formed on the readout layer 15 by DC sputtering using a C target in an atmosphere of Ar. Further, the lubricating layer 17 made of perfluoropolyether (hereinafter referred to as PFPE) (3 nm) is formed on the dielectric layer 16 by application.

The recording film of this magnetic disk is irradiated with focused laser light (i.e., a laser spot) so as to record or reproduce (detect) a signal using a magnetic head or an optical head, depending on an information signal, thereby making it possible to record and reproduce recording marks which are recorded in high density.

Alternatively, a recording and reproducing apparatus employing the magnetic disk may be used. In this case, the disk is rotated, and is modulated with a recording signal which is modulated with an information signal, by a magnetic head while the disk is being irradiated with laser light by an optical head, so that the information is recorded. During signal reproduction, a laser spot having only a single plane of polarization is emitted by the optical head, and reflected light or transmitted light from a recorded magnetic domain is detected to reproduce a signal.

The magnetic recording medium of the present invention can overcome the following drawbacks of conventional magnetic recording media: (1) particularly when an attempt is made to record a small mark at a recording film, a recorded magnetic domain is expanded or extinguished by displacement of a magnetic domain wall, so that stable recording cannot be achieved; and (2) this phenomenon particularly becomes significant when recording density is high, and a problem with thermal stability deteriorates reliability after long-time storage.

Specifically, in the magnetic recording medium of the present invention, a memory layer is formed on a disk substrate on which concaves and convexes are formed, and the memory layer is an aggregate of isolated magnetic grains. Therefore, even when recording is performed in high density, marks can be stabilized. Also, even when there is a change in ambient temperature or the like, the small structures of the recording film can be stabilized. Therefore, a magnetic recording medium having excellent stability against temperature changes and excellent signal characteristics can be achieved.

### EMBODIMENT 3

FIG. 4 shows a magnetic disk 30 according to this embodiment. The magnetic disk 30 comprises a transparent disk substrate 31 made of glass, a photopolymer layer 32, an underlying dielectric layer 33, and a magnetic recording film including a memory layer 34, an intermediate layer 35, a control layer 36, and a readout layer 37, which are laminated one on top of another in the stated order. On the resultant multilayer structure, a protective layer 38 and a lubricating layer 39 for protection of the magnetic recording film and sliding movement of a magnetic head are further laminated.

Pit shapes are transferred to the photopolymer layer 32 using a stamper in which pits are formed, and the photopolymer layer 32 is then cured, before formation of the underlying dielectric layer 33. Thereby, pits for tracking servo and address detection are formed. A pit region for servo and a data region for recording information are formed in a recording track. A track pitch is 0.25 μm.

This magnetic disk is applicable to DWDD, which sequentially displaces domain walls immediately when a laser beam reaches the domain walls by using a temperature gradient produced by the laser beam and detects the displacement of the domain walls, thereby improving the sensitivity of signal detection during reproduction and enabling super-resolution reproduction.

With this feature, a reproduced magnetic domain will always have a constant maximum amplitude irrespective of the size of a recorded magnetic domain. Even when a signal is reproduced using an optical head or a magnetic head, such as a GMR head, then if a transferred magnetic domain in the readout layer is expanded by a temperature gradient caused by a light beam or the like, the reproduced signal will always have an amount corresponding to the constant maximum amplitude.

The magnetic disk 30 can be fabricated as follows.

First, the disk substrate 31 is prepared, and a photopolymer is applied onto the disk substrate 31. Pits and grooves are transferred to the photopolymer 32 applied on the substrate, using a stamper, and then the photopolymer 32 is cured by irradiation with ultraviolet light.

Next, a target is set in a DC magnetron sputtering apparatus and the disk substrate is fixed to a substrate holder. Thereafter, the chamber is evacuated to a high vacuum of 6*10⁻⁶ Pa or less using a turbomolecular pump. Ar gas and N₂ gas are introduced into the chamber to 0.3 Pa while evacuation is maintained. The underlying dielectric layer 33 made of AlTiN (35 nm) is formed by reactive sputtering while the substrate is being rotated.

Kr gas is introduced to 0.5 Pa. An alloy target is used to form the memory layer 34 made of TbFeCo (60 nm) by DC magnetron sputtering. After the formation of the memory layer 34, an ion gun is used to perform ion etching, thereby forming small structures in the memory layer. As a result, the magnetic domain wall energy of the memory layer 34 is distributed in the in-plane direction.

Next, Ar gas is introduced into the chamber to 1.5 Pa. While the substrate is being rotated, the intermediate layer 35 made of TbFeCo, the control layer 36 made of TbFeCoCr, and the readout layer 37 of GdFeCo are successively laminated by sputtering using alloy targets having the respective corresponding compositions. These compositions can be caused to have desired values by adjusting the molar ratios of the targets.

Further, the protective layer 38 made of diamond-like carbon (DLC) (5 nm) is formed on the readout layer 37 by reactive RF sputtering using a C target in an atmosphere of a mixture of Ar and CH₄. The lubricating layer 39 (4 nm) made of perfluoropolyether (hereinafter referred to as PFPE) is formed on the protective layer 38 by application.

FIG. 8 shows a relationship between the resistivity in the in-plane direction of the memory layer of the magnetic recording medium, and the etching time of the ion gun. As shown in the figure, the resistivity in the in-plane direction of the memory layer increases with an increase in the etching time after formation of the memory layer. Further, it was confirmed that, when the resistivity reaches 500 μΩcm or more, a fine recording film of 100 nm or less can be stably formed.

The composition of the alloy target was adjusted so that the memory layer 34 made of TbFeCo has a compensation composition temperature of 130° C. and a Curie temperature of 320° C. With this composition, the coercive force is 8 koe at room temperature.

In the recording film of this embodiment, as is similar to that shown in FIG. 14, the coercive force Hc decreases with an increase in the temperature T, and the saturated magnetization Ms increases with an increase in the temperature from the compensation composition temperature. Thereby, when reproduction is performed using a GMR head, the sensitivity of detection of a reproduced signal can be improved. Also, the coercive force is small at increased temperature, so that recording is easily performed using the magnetic head, and a large recording magnetic field is no longer required.

Since the chamber is evacuated by a turbomolecular pump, the recording film absorbs remnant hydrogen during formation of the layer due to a difference in evacuation rate between molecular weights, so that a compound of a rare earth metal or a transition metal and hydrogen is included. Thereby, even when recording is performed in high density, the small structures in the layer are stabilized, resulting in stable recorded magnetic domains and excellent signal characteristics. Also, when a small magnetic domain is recorded by a magnetic head, the recorded magnetic domain can be stabilized. Therefore, in the magnetic recording medium, even when recording and reproduction are repeatedly performed, excellent signal characteristics and excellent stability against temperature changes are achieved. This can be confirmed from a distribution of hydrogen contents and coupled states between hydrogen and other elements.

The recording film of the magnetic disk is irradiated with a laser beam, and a magnetic domain in the readout layer which is expanded by magnetic domain wall displacement is detected as a rotation of the plane of polarization of an incident light spot. Thereby, it is possible to record and reproduce a recording mark smaller than those detectable with a laser spot for reproduction.

Alternatively, by recording and reproducing (detecting) a signal using a magnetic head, it is possible to record and reproduce a recording mark smaller than those detectable with a laser spot for reproduction.

Alternatively, a recording and reproducing apparatus employing the magnetic disk may be used. The disk is rotated, and is irradiated with a laser beam spot along the track, so that information can be recorded onto the disk using a magnetic head. In this case, in the recording film, the coercive force decreases at high temperature, so that recording can be performed using the magnetic head. By detecting a recorded magnetic domain using a GMR head while temperature is increased by irradiation with a laser beam, a signal can be reproduced. In this case, the saturated magnetization Ms increases with an increase in temperature, and reaches a maximum at 70° C. Therefore, the detection sensitivity of the GMR head is improved, and a reproduced signal is increased.

The magnetic recording medium of the present invention can overcome the following drawbacks of conventional magnetic recording media: (1) when small magnetic domains are recorded in high density, a recording mark is unstable due to displacement of a magnetic domain wall of a recorded magnetic domain; (2) a change in ambient temperature, or an increase in temperature of the magnetic disk when the recording film is irradiated with a laser beam, or the like causes a stray magnetic field and its temperature characteristics, which in turn change a recording mark, so that a reproduced signal is deteriorated; and (3) crosstalk, crosserase, a deterioration in recorded and reproduced signals, or a reduction in reproduced signal amount occurs.

Also, in the magnetic recording medium of this embodiment, a signal is reproduced by a temperature gradient caused by irradiation with a light beam using DWDD. Therefore, the readout layer is amorphous and does not have small structures, and has a film structure in which a magnetic domain wall is easily displaced, while the recording layer of the memory layer has small structures. The readout layer, in which a signal from the memory layer is transferred and expanded, has a composition such that the saturated magnetization Ms reaches a maximum at 90° C., so that a reproduced signal can be further increased.

Also, even when a small magnetic domain is recorded, the recorded magnetic domain can be stabilized. Even when recording and reproduction are repeatedly performed by irradiation with a laser spot, it is possible to achieve recording and reproduction with excellent signal characteristics.

In other words, in the magnetic recording medium of the present invention, even when recording and reproduction are performed in high density, stable reproduced signal characteristics are obtained. Further, since recorded magnetic domains in an information track are formed in a stable shape, crosswrite and crosstalk from adjacent tracks can be reduced during recording and reproduction.

In the magnetic disk 30 of this embodiment described above, the memory layer 34 is ion-etched. Alternatively, a very thin oxide film may be formed on a surface closer to the underlying layer or the intermediate layer of the memory layer. Also in this case, small and isolated magnetic grains can be obtained in the memory layer.

Also, in the magnetic disk 30 of this embodiment described above, the photopolymer 32 is applied on the disk substrate 31. Alternatively, a glass substrate may be directly subjected to imprinting, a surface property of the disk substrate may be changed by etching or the like, a glass substrate may be subjected to direct processing or transfer by heated melting, a plastic substrate may be molded, or the like.

In this embodiment described above, the track pitch is 0.25 μm. It is more advantageous that the recording track in which information is recorded has a width of 0.6 μm or less, and a recorded domain in which the shortest mark length of recorded information is 0.35 μm or less is recorded.

### EMBODIMENT 4

A magnetic disk according to this embodiment comprises, as in Embodiment 3, a disk substrate which is a polished flat glass plate, a magnetic recording film including a dielectric layer 33, a readout layer 37, an intermediate layer 35, and a memory layer 34, and a dielectric protective layer 38 and a lubricating layer 39 for protection of the magnetic recording film and sliding movement of a magnetic head.

Here, the magnetic disk 30 of this embodiment has a track pitch of 0.3 μm and a prepit diameter of 0.25 μm.

In the magnetic disk 30, pits for servo and address detection are formed on a recording track, and information is recorded in a data region thereof. The pits are used for tracking servo and address detection. The pits are fabricated into shapes having different surface roughnesses. Alternatively, the pits are magnetically recorded and formed by magnetic contact duplication or using a servo writer or the like, after a magnetic recording film is formed.

When pits are formed by changing a surface shape, such as surface roughness, of the disk substrate 31, a stamper in which prepits are formed in a glass master plate using a photoresist or the like, is used to transfer the prepits to the disk substrate 31 by imprinting or the like.

Alternatively, pits are directly formed in a stamper or a disk substrate by ion etching while controlling the concave-and-convexes shape, surface roughness or the like of the pit portion.

The surface roughness may also be changed by a combination of bottom surfaces of prepits formed in the stamper with ion etching.

In the magnetic recording medium of Embodiment 4 of the present invention of FIG. 4, the dielectric protective layer 38 and the lubricating protective layer 39 are formed on a thin film surface of the magnetic recording films 34, 35, 36, and 37. A signal is recorded and reproduced (detected) using a magnetic head above the lubricating layer, thereby making it possible to record and reproduce recording marks which are recorded in high density. By recording and reproducing (detecting) a signal using the magnetic head, it is possible to record and reproduce a recording mark smaller than those detectable with a laser spot for reproduction.

In a recording and reproducing apparatus employing this magnetic disk, information is recorded using a magnetic head while the disk is being rotated. In this case, if the memory layer has a coercive force of 10 koe, recording can be performed using a magnetic head. During signal reproduction, a GMR head is used to detect a signal from a recorded magnetic domain. In this case, if a memory layer is used which has characteristics such that the coercive force decreases with an increase in temperature due to irradiation with laser light, and the saturated magnetization Ms increases with an increase in temperature, and the composition is adjusted so that the saturated magnetization Ms reaches a maximum at 60° C., the sensitivity of detection using the GMR head is improved and the reproduced signal is increased. Also, if DWDD is used, reproduction can be performed while the amplitude of the reproduced signal can be further increased.

This magnetic disk can be fabricated as follows.

First, a disk substrate is prepared.

The disk substrate is introduced into an apparatus for producing a magnetic recording medium shown in FIG. 9.

In the production apparatus, a main chamber 73 is connected via a vacuum transport chamber 70 and a load/unload chamber 72 to a degasing chamber 71. A plurality of vacuum process chambers 81, 82, 83, 84, 85, 86, and 87 are connected to the main chamber 73, and a magnetic disk is moved through the main chamber 73 into the vacuum process chambers 81, 82, 83, 84, 85, 86, and 87, in which layers are formed. The degasing chamber 71 comprises a load chamber 74, an unload chamber 75, and a heating chamber 77, which are linked together.

The disk substrate is inserted from the load chamber 74 into the degasing chamber 71, and is moved through the degasing chamber 71 while being heated by the heating chamber 77, so that adsorbed gas is degassed from the disk substrate. In the unload chamber 75 of the degasing chamber 71, the disk substrate is fixed to a substrate holder, a mask is fixed over the disk substrate, and the disk substrate is moved through the vacuum transport chamber 70 to the main chamber 73. Next, the disk substrate is moved from the main chamber 73 to the vacuum process chamber 81. The vacuum process chamber 81 is evacuated to a high vacuum of 8*10⁻⁶ Pa or less by a turbomolecular pump. Ar gas and O₂ gas are introduced into the chamber to 0.3 Pa while evacuation is maintained. While the substrate is being rotated, the dielectric layer 33 made of TaO (10 nm) is formed by reactive sputtering.

Next, the disk substrate is moved through the main chamber 73 to the vacuum process chamber 82 for formation of a memory layer made of TbFeCo. Here, the vacuum process chamber 82 is evacuated to a high vacuum of 7*10⁻⁶ Pa or less by a turbomolecular pump. In this case, the partial pressure of hydrogen in the vacuum process chamber 82 is 2*10⁻⁸ Pa. The vacuum atmosphere can be controlled by the rotational speed of the turbomolecular pump. Xe gas is introduced into the vacuum process chamber 82 to 0.8 Pa while evacuation is maintained. The memory layer 34 made of TbFeCo (60 nm) is formed by DC magnetron sputtering using an alloy target of TbFeCo while the substrate is being rotated.

Here, the film composition of TbFeCo can be caused to have a desired value by adjusting the composition of the alloy target and conditions for formation of the film. Also, under some conditions for a film formation atmosphere including Xe gas in the vacuum process chamber, a film formation rate, and the like, small structures are formed in the memory layer 34 of TbFeCo during film formation by sputtering, resulting in a micro film structure in which small magnetic grains which are in the shape of a column and are magnetically isolated are formed as in FIG. 2.

Further, the disk substrate is moved through the main chamber 73 to the vacuum process chambers 83, 84, and 85 successively, so that the intermediate layer 35 made of TbFeCoAl (15 nm), the control layer 36 made of TbFeCoCr (10 nm), and the readout layer 37 made of GdFeCo (35 nm) are laminated, respectively.

Note that, as in the formation of the memory layer 34 of TbFeCo, Xe is also introduced into the vacuum process chambers 83 and 84 during formation of the intermediate layer 35 made of TbFeCoAl and the control layer 36 made of TbFeCoCr in the vacuum process chambers 83 and 84.

Next, the disk substrate is moved to the vacuum process chamber 86, in which the protective layer 38 made of diamond-like carbon (DLC) (3 nm) is formed on the readout layer 37 by reactive RF sputtering using a C target in an atmosphere of a mixture of Ar and CH₄. The magnetic disk thus formed is then cooled in the vacuum process chamber 87, and is moved via the load/unload chamber 72 to the outside of the vacuum apparatus.

Further, a lubricating protective layer made of perfluoropolyether (hereinafter referred to as PFPE) (2 nm) is applied onto the protective layer as the disk is pulled up by a dipping apparatus.

Here, the film composition of the memory layer 34 made of TbFeCo is adjusted by setting a target composition and conditions so that the compensation composition temperature is 140° C. and the Curie temperature is 330° C. Also, here, the recording film is not etched after the formation of the memory layer 34, but the recording film may be held in a vacuum or in an Ar atmosphere containing hydrogen or nitrogen in the vacuum process chamber so that gas molecules, such as hydrogen or nitrogen, may be occluded or adsorbed into the film.

Since the memory layer has such a composition and contains such gas molecules, micro film structures formed of isolated magnetic grains are stable, and the coercive force is 10 koe or more at room temperature. As a result, even when a small magnetic domain is recorded using a magnetic head, a stable recorded magnetic domain can be formed. Also, even when recording and reproduction are repeatedly performed using a magnetic head, recording and reproduction with excellent signal characteristics can be achieved.

The magnetic recording medium of the present invention can overcome the following drawbacks of conventional magnetic recording media: (1) when small magnetic domains are recorded in high density, a recording mark is unstable due to displacement of a magnetic domain wall of a recorded magnetic domain; (2) a change in ambient temperature, an increase in temperature of the magnetic disk when the recording film is irradiated with a laser beam, or the like causes a stray magnetic field and its temperature characteristics, which in turn change recording marks, so that a reproduced signal is deteriorated; and (3) crosstalk, crosserase, a deterioration in recorded and reproduced signals, or a reduction in reproduced signal amount occurs.

Specifically, in the magnetic recording medium of the present invention, small structures are formed by sputtering using Xe gas or the like, and the memory layer is caused to contain hydrogen by a simple method, so that the memory layer is stabilized. Therefore, even when small magnetic domain are recorded in high density, stable recording characteristics and reproduced signal characteristics can be achieved. Also, since the memory layer has a large coercive force at room temperature, even when ambient temperature or the like changes, a stable recorded magnetic domain can be formed, resulting in a magnetic recording medium having excellent signal characteristics and high reliability.

Further, since a recorded magnetic domain is formed in a stable shape in an information track, crosswrite and crosstalk from adjacent tracks can be reduced during recording and reproduction.

### EMBODIMENT 5

As shown in FIG. 6, a magnetic disk 50 of this embodiment comprises an underlying dielectric layer 52, a magnetic recording film including a memory layer 53, an intermediate layer 54, and a readout layer, and a protective layer 56 and a lubricating layer 57 for protection of the magnetic recording film and sliding movement of a magnetic head, which are laminated, one on the top another in the stated order, on a polished disk substrate 51 made of an Al alloy.

In the disk substrate 51, a guide groove including grooves 58a and 58b and lands 59a and 59b is formed in a track for recording information. A pit region for servo and a data region for recording information are formed in the recording track. Pits for tracking servo and address detection are formed in the pit region. The pits are formed by concaves and convexes, different surface roughnesses, or magnetic recording. A track pitch is 0.3 μm.

When the pits are concaves and convexes or different surface roughnesses, a stamper in which pits are formed is used to transfer the pits to the disk substrate 51 made of a metal by imprinting. The concave-and-convex shape, surface roughness or the like of the pit is controlled by ion etching, so that concaves and convexes are formed in the stamper or directly in the disk substrate.

Even when the underlying metal layer 52 of AgCu or the like or the dielectric layer 52 made of ZnSSiO₂ is formed on the disk substrate 51 having such concaves and convexes or surface roughness, the pits in a surface of the disk substrate 51 are also formed in the underlying dielectric layer 52. As a result, the pit portion is formed as a servo pit having a small surface roughness.

The magnetic recording medium of this embodiment is irradiated with a laser beam from the lubricating layer side on which the recording film is formed, and a signal is recorded and reproduced (detected) using a magnetic head, thereby making it possible to record and reproduce a recording mark smaller than those detectable with a laser spot for reproduction.

The magnetic disk 50 can be fabricated as follows.

First, the disk substrate 51 is prepared. Pits are formed in a surface of the disk substrate 51 using a photopolymer. Portions other than the pits are etched by an ion gun through a mask to cause the pits to have a surface roughness Ra of 0.5 nm or more. Thereby, pits having different surface roughnesses Ra can be formed. In this case, pits having a small surface roughness can be used for servo. Alternatively, the pits are magnetically recorded and formed by magnetic contact duplication or using a servo writer or the like, after a magnetic recording film is formed on the disk substrate.

Next, using a sputtering apparatus, the dielectric layer 52, the recording film including the memory layer 53, the intermediate layer 54, and the readout layer 55, and the protective layer 56 are formed using a film forming apparatus of FIG. 9 as in Embodiment 4.

A target is set in a sputtering apparatus and the disk substrate 51 is fixed to a substrate holder. Thereafter, the chamber is evacuated to a high vacuum of 8*10⁻⁶ Pa or less using a turbomolecular pump. Ar gas is introduced into the chamber to 0.2 Pa while evacuation is maintained. A metal layer made of AgCu (20 nm) is formed while the substrate is being rotated. Further, Ar of 0.4 Pa is introduced, and a ZnSSiO₂ layer (10 nm) is formed by RF magnetron sputtering to form the dielectric layer 52.

Next, Ar gas is introduced into the chamber to 2.0 Pa while evacuation is maintained. The memory layer 53 made of TbFeCo (80 nm) is formed by DC magnetron sputtering using an alloy target of TbFeCo while the substrate is being rotated. Here, the film composition of TbFeCo can be caused to have a desired value by adjusting the molar ratio of the alloy target composition and conditions for formation of the film.

Next, the memory layer 53 of TbFeCo is etched using an ion gun in an Ar atmosphere containing hydrogen and nitrogen. Thereafter, the memory layer 53 is held for 30 sec in an atmosphere containing 20 at % hydrogen. Thereby, the gas molecule is captured into the memory layer 53, and is stably bound with the rare earth metal. In this case, by adjusting conditions for etching, the evenness of the surface of the memory layer 53 can be adjusted.

Further, the intermediate layer 54 of TbFeCoCr and the readout layer 55 of GdFeCo are successively laminated by sputtering using alloy targets having the respective compositions in an atmosphere of Ar gas having 1.5 Pa while the substrate is being rotated. Here, the compositions of TbFeCoCr and GdFeCo of the magnetic recording film can be caused to have desired values by adjusting the molar ratios of the target compositions and conditions for formation of the films.

Here, the composition of the memory layer 53 made of TbFeCo is adjusted so that the compensation composition temperature is −20° C. and the Curie temperature is 310° C.

As a result, the magnetic recording medium has film characteristics such that the saturated magnetization Ms reaches a maximum at 120° C. which is a temperature attained by irradiation with a light beam, and the coercive force Hc decreases with an increase in temperature. Therefore, even when a small magnetic domain is recorded, a stable recorded magnetic domain can be formed. Even when recording and reproduction are repeatedly performed using a magnetic head, recording and reproduction with excellent signal characteristics can be achieved.

The protective layer 56 made of amorphous carbon (a:C) (7 nm) is formed on the readout layer 55 by DC sputtering using a C target in an Ar atmosphere. The lubricating layer 57 made of perfluoropolyether (hereinafter referred to as PFPE) is formed on the protective layer 56 by application using a spin coater.

Information can be recorded onto this magnetic recording medium by modulating a recording magnetic field using a magnetic head while the disk is being rotated and irradiated with a laser beam spot along the track. In this case, since the coercive force of the memory layer 53 decreases at high temperature, recording can be performed by the magnetic field of the magnetic head. During signal reproduction, a recorded or reproduced magnetic domain is detected using a GMR head while a transferred magnetic domain is expanded by magnetic domain wall displacement using the above-described DWDD with the temperature being increased by irradiation with a laser beam. In this case, the saturated magnetization Ms of the readout layer increases with an increase in temperature. The reproduced signal reaches a maximum at 100° C., so that the sensitivity of detection by the GMR head is improved and the reproduced signal is increased.

Here, FIG. 8 shows a relationship between the resistivity in the in-plane direction of the memory layer of the magnetic recording medium, and the etching time of the ion gun, which is similar to that of Embodiment 3. Therefore, by setting the etching time, power and the like so that the resistivity in the in-plane direction of the memory layer increases after formation of the memory layer, the resistivity can be caused to be 500 μΩcm or more, and a fine recording film of 100 nm or less can be stably formed.

In this case, it is considered that isolated magnetic grains are formed in the memory layer, and there is a close relation between the resistivity of the recording layer and the small magnetic grain. Therefore, by setting the etching time to be 6 sec or more, the resistivity of the memory layer can be caused to be large. When the memory layer is formed under conditions which cause the resistivity to increase, small structures can be formed in the memory layer, so that small isolated magnetic grains can be formed.

The magnetic recording medium of the present invention can overcome the following drawbacks of conventional magnetic recording media: (1) when the recording film is irradiated with a laser beam, a temperature of the magnetic disk increases, so that a small recorded magnetic domain is deteriorated. Particularly, a recorded magnetic domain becomes unstable due to an increase in temperature of the magnetic disk and a change in temperature during a cooling process, so that the recorded domain is deteriorated due to displacement of a magnetic domain wall; and (2) when servo pits are magnetically formed, characteristics of a servo signal is also changed, or this causes a decrease in recording and reproduction characteristics.

Specifically, in the magnetic recording medium of the present invention, the memory layer has a structure in which isolated small magnetic grains are stably formed, thereby making it possible to stably record a small recorded magnetic domain irrespective of a change in ambient temperature, or a change in temperature of the magnetic disk when the recording film is irradiated with a laser beam during recording and reproduction. As a result, a magnetic recording medium having excellent thermal endurance and signal characteristics can be achieved in which, even when the temperature of the recording film is increased by a light beam or the like and a signal is reproduced using a magnetic head, such as a GMR head.

Also, even when recording and reproduction are performed in high density, stable reproduced signal characteristics are obtained. Further, since the recorded magnetic domain in the information track is formed in a stable shape, crosswrite and crosstalk from an adjacent track can be reduced during recording and reproduction.

In this embodiment above, the track pitch has been assumed to be 0.3 μm. It is more advantageous that the groove in which information is recorded has a width of 0.6 μm or less, and a recorded domain in which the shortest mark length of recorded information is 0.3 μm or less is recorded.

### EMBODIMENT 6

As shown in FIG. 7, a structure of a magnetic disk 60 of this embodiment comprises a dielectric layer 62, a readout layer 63 having an amorphous film structure, an intermediate layer 64, a memory layer 65 having small isolated column-shaped magnetic grains, and a dielectric layer 66, which are laminated, one on the top of another in the stated order, on a disk substrate 61 made of transparent polycarbonate. On the resultant structure, an overcoat layer (not shown) for protecting the recording film is formed.

Note that the memory layer 65 for holding information, the readout layer 63 for detecting information based on displacement of a magnetic domain wall, and an intermediate layer (or an intermediate isolating layer) 64 for controlling exchange-coupling between the readout layer and the memory layer, constitute a magnetic recording film.

A guide groove including grooves and lands is formed in a track for recording information in the disk substrate 61. A pit region for servo and a data region for recording information are formed in the recording track. Pits for tracking servo and address detection are formed in the pit region. A track pitch is 0.35 μm.

The magnetic disk 60 can be fabricated as follows.

First, the disk substrate 61 is prepared. Grooves and lands, and pits are formed in the disk substrate 61 by injection molding.

Next, a Si target is set in a DC magnetron sputtering apparatus and a disk substrate is fixed to a substrate holder. Thereafter, the chamber is evacuated to a high vacuum of 8*10⁻⁶ Pa or less using a turbomolecular pump. Ar gas and N₂ gas are introduced into the chamber to 0.4 Pa while evacuation is maintained. The dielectric layer 62 made of a SiN film is formed by reactive sputtering while the substrate is being rotated.

The substrate is moved in the vacuum chamber while evacuation is maintained. Ar gas is introduced into the chamber to 0.6 Pa. The readout layer 63 made of GdFeCoCr (30 nm) is formed by DC magnetron sputtering using an alloy target of GdFeCoCr while the substrate is being rotated. The substrate is moved in the vacuum chamber while evacuation is maintained. Ar gas is introduced into the chamber to 1.5 Pa. The intermediate layer 64 made of TbFeCoCr (20 nm) is formed by DC magnetron sputtering using an alloy target of TbFeCoCr while the substrate is being rotated. Further, Kr gas containing hydrogen gas (partial pressure: 0.5%) is introduced into the chamber to 1.0 Pa while evacuation is maintained. The memory layer 65 made of TbFeCo (70 nm) is formed by DC magnetron sputtering using an alloy target of TbFeCo while the substrate is being rotated.

Here, the film compositions of the layer compositions TbFeCo, TbFeCoCr, and GdFeCo can be caused to have desired values by adjusting the molar ratio of the alloy target composition and conditions for formation of the film.

Further, Ar gas and N₂ gas are introduced into the chamber to 0.3 Pa. The dielectric layer 66 of SiN (4 nm) is formed by reactive sputtering while the substrate is being rotated.

Further, a UV-curable resin (e.g., a polyurethane material) is applied onto the dielectric layer 66 using a spin coater, and is cured by irradiation with ultraviolet light to form the overcoat layer.

Here, the film composition of the memory layer made of TbFeCo is adjusted so that the compensation composition temperature is −50° C. and the Curie temperature is 310° C. As a result, the recording film of the magnetic recording medium has film characteristics such that the saturated magnetization Ms increases at temperature caused by irradiation with light beam, and the coercive force Hc decreases with an increase in temperature from room temperature.

Also, the magnetic anisotropy in the out-of-plane direction of the readout layer 63 is larger than the magnetic anisotropy of the intermediate layer 64.

Further, the magnetic domain wall width in a depth direction of the readout layer 63 is larger than that in the in-plane direction thereof. Therefore, a recorded domain in the memory layer is stably transferred to the readout layer.

The magnetic recording medium of this embodiment, similarly to Embodiment 2, is applicable to DWDD, which sequentially displaces domain walls immediately when a laser beam reaches the domain walls by using a temperature gradient produced by a light beam and detects the displacement of the domain walls, thereby improving the sensitivity of signal detection during reproduction and enabling super-resolution reproduction.

Thereby, a reproduced magnetic domain will always have a constant maximum amplitude irrespective of the size of a recorded magnetic domain. Therefore, even when a signal is reproduced using an optical head or a magnetic head, such as a GMR head, then if a magnetic domain transferred to the readout layer is expanded by a temperature gradient caused by a light beam or the like, the reproduced signal will always have an amount corresponding to the constant maximum amplitude. Particularly, the recording film is irradiated with a laser beam through the disk substrate, and a magnetic domain in the readout layer which is expanded by magnetic domain wall displacement is detected using a magnet head as a rotation of the plane of polarization of an incident light spot. Thereby, it is possible to record and reproduce a recording mark smaller than those detectable with a laser spot for reproduction.

Specifically, in the magnetic recording medium of this embodiment, information is recorded by modulating a recording magnetic field using a magnetic head while the disk is being rotated and irradiated with a laser beam spot along the track. In this case, in the recording film, the coercive force decreases at high temperature, so that recording can be performed by the magnetic field of the magnetic head. During signal reproduction, a recorded magnetic domain is detected using a GMR head while a transferred magnetic domain is expanded by magnetic domain wall displacement using DWDD with the temperature being increased by irradiation with a laser beam. In this case, if the recording film has characteristics such that the coercive force Hc decreases and the saturated magnetization Ms increases to a maximum temperature, with an increase in the temperature T, the saturated magnetization Ms increases with an increase in temperature and reaches a maximum at 100° C., so that the sensitivity of detection by the GMR head is improved and a reproduced signal is increased.

In the magnetic recording medium of this embodiment, a signal is reproduced by a temperature gradient caused by irradiation with a light beam using DWDD. Therefore, the readout layer is amorphous and does not have small structures, so that domain walls are easily displaced, while the memory layer of the recording film has small structures, so that, even when a small magnetic domain is recorded, a stable recorded magnetic domain can be formed. Also, even when recording and reproduction are repeatedly performed by irradiation with a laser spot, it is possible to achieve recording and reproduction with excellent signal characteristics.

Therefore, the magnetic recording medium of the present invention can overcome the following drawbacks of conventional magnetic recording media: (1) particularly when an attempt is made to record a small mark, a recorded magnetic domain is expanded or extinguished by displacement of a magnetic domain wall, so that stable recording cannot be achieved; (2) this phenomenon particularly becomes significant when recording density is high, and a problem with thermal stability deteriorates reliability after long-time storage; (3) transfer of a small recorded domain to the readout layer becomes unstable, so that a reproduced signal is deteriorated; (4) when the recording film is irradiated with a laser beam, a recorded magnetic domain becomes unstable due to an increase in temperature of the magnetic disk and a change in temperature during a cooling process, so that the recorded domain is deteriorated due to displacement of a magnetic domain wall; and (5) when servo pits are magnetically formed, characteristics of servo signals are also changed, or this causes a decrease in recording and reproduction characteristics.

Specifically, a memory layer having micro column structures as shown in FIG. 7 is formed on a disk substrate, and is caused to contain a hydrogen element, so that isolated magnetic grains are formed in the memory layer, whose film structures are stabilized. In addition, pinning sites of magnetic domain walls cause coercive force to increase, so that marks recorded in high density can be stabilized. Also, even when ambient temperature or the like changes or when the temperature of the magnetic disk is changed by irradiating the recording film with a laser beam during recording and reproduction, the small structures of the recording film can be stabilized, and transfer to the readout layer can be stably performed, resulting in a magnetic recording medium having excellent stability against temperature changes and excellent signal characteristics. Also, when a signal is reproduced using a magnetic head, such as a GMR head, excellent thermal endurance can be achieved. Also, since a recorded magnetic domain in an information track is formed in a stable shape, crosswrite and crosstalk from adjacent tracks can be reduced during recording and reproduction.

In this magnetic recording medium, as can be seen from FIG. 5, by increasing the Ar pressure during film formation, the resistivity in the in-plane direction of the memory layer can be increased. Further, it was confirmed that, when the resistivity reaches 500 μΩcm or more, a small recording film of 100 nm or less can be stably formed.

In this case, it is considered that isolated magnetic grains are formed in the memory layer, and there is a close relation between the resistivity of the recording film and the small magnetic grains. Therefore, when the memory layer is formed under conditions which cause the resistivity to increase, small structures can be formed in the film of the memory layer, and isolated small magnetic grains can be formed.

In this embodiment above, the track pitch has been assumed to be 0.35 μm. It is more advantageous that the groove in which information is recorded has a width of 0.6 μm or less, and a recorded domain in which the shortest mark length of recorded information is 0.3 μm or less is recorded.

In this embodiment, it has been described that the guide groove and the prepit are formed by injection molding. Alternatively, pits and grooves may be formed by curing a photopolymer, or a substrate may be formed by subjecting heated glass to imprinting, with which the same effect is obtained.

### EMBODIMENT 7

### Recording and Reproducing Apparatus for Magnetic Recording Medium

A structure of a recording and reproducing apparatus for the magnetic recording medium of the present invention will be described.

As shown in FIG. 10, the recording and reproducing apparatus comprises at least: a magnetic recording medium 101; a magnetic head 102 including a means for detecting a format signal of the magnetic recording medium 101, a means for reading a data signal from the magnetic recording medium 101, and a means for writing a data signal onto the magnetic recording medium 101; and a spindle motor 103.

The magnetic head 102 is connected to and controlled by a control/detection circuit 106 for the magnetic head.

The spindle motor 103 is connected to and controlled by a motor drive/control circuit 107.

Further, an optical head 104 is provided at a position facing the magnetic recording medium 101. The optical head 104 comprises optical elements 108, 109, 110, and 111 which are selected from a laser, a photodetector, a prism, a collimator lens, an objective lens, a hologram element, and the like. The optical head 104 is connected to and controlled by a laser drive circuit 105. The optical head 104 is also connected to a photodetector 112. Note that the optical head 104 may be provided on the same side on which the magnetic head is provided.

In the thus-configured recording and reproducing apparatus, a signal is recorded to or reproduced from the magnetic disk 101 attached to the spindle motor 103 using the magnetic head 102 controlled by the magnetic head control/detection circuit 106. The recording and reproduction are performed by the magnetic head 102 while the optical head 104 is irradiating the disk with laser light controlled by the laser drive circuit 105. In this case, the motor drive/control circuit 107 causes the spindle motor 103 to perform a rotation drive control of a motor, a servo control of laser light, and the like. Reflected light from the optical head 104 is detected by the photodetector 112, and is utilized for a focus servo control and a tracking servo control.

Note that the magnetic head 102 and the optical head 104 or the objective lens 108 may be integrated together. The semiconductor laser 111 of the optical head 104 may be provided separately from the objective lens, and a waveguide may be provided therebetween so as to introduce laser light from the light source to the objective lens.

By using the thus-configured recording and reproducing apparatus, information can be recorded to or reproduced from the memory layer of the magnetic disk of the present invention which has a fine structure in which magnetic grains are isolated and is stably coupled with hydrogen, based on a surface shape or a magnetically recorded pit, while tracking servo is being performed.

Also, even when small magnetic domains are recorded and reproduced in high density, stable recorded magnetic domains can be formed, and a reproduced signal can be detected, i.e., recording and reproduction with excellent signal characteristics can be achieved.

### OTHER EMBODIMENTS

A magnetic disk of this embodiment has a fine structure in the memory layer in which magnetic grains are isolated, and the memory layer has stable microstructures which contain hydrogen. Therefore, even when small recorded domains are recorded in high density, stable recorded magnetic domains can be achieved.

Note that the memory layer of the magnetic recording medium of this embodiment is an aggregate of mutually isolated magnetic grains with any of the following structures: the magnitude of magnetization is distributed in the in-plane direction of the memory layer; the magnitude of coercive force is distributed in the in-plane direction of the memory layer; perpendicular magnetic anisotropy is distributed in the in-plane direction of the memory layer; and the magnetic domain wall energy density or the magnetic domain wall width is distributed in the in-plane direction of the memory layer.

More advantageously, the magnetic domain wall width in the in-plane direction of the memory layer is smaller than a film thickness of the layer. The same or higher level of effect can be obtained when magnetic domain wall energy density differs between the layers of the recording film.

It has been described above that the resistivity in the in-plane direction of the memory layer is 500 μΩcm or more or the width of the magnetic grain is 50 nm or less. The present invention is not limited to these values. The same effect is obtained as long as a small recorded domain can be stabilized by the aggregate of mutually isolated magnetic grains.

If the magnetic domain wall energy density of the intermediate layer is larger than that of the readout layer or if the magnetic domain wall energy of the readout layer differs between in the in-plane direction and in the out-of-plane direction, the same or higher level of effect is obtained.

Either the magnetic domain wall width in the depth direction or the magnetic domain wall width in the in-plane direction of the intermediate layer may be smaller than the film thickness of the intermediate layer.

Any of the following structures may be employed: the disk substrate or the underlying layer of the magnetic recording film are embossed; a surface of the underlying layer is processed to have concaves and convexes; small concaves and convexes corresponding to recording marks are formed; and the like.

The memory layer can be formed by sputtering in an atmosphere containing Ar, Kr, and Xe or in an atmosphere containing at least one of Ne, Ar, Kr, and Xe or a combination thereof.

The magnetic recording medium can be fabricated by: causing the recording film to take in gas molecules in a vacuum in a vacuum process chamber by etching using an ion gun or holding the medium in an atmosphere containing hydrogen and nitrogen to cause the gas molecules to be occluded or adsorbed into the recording film; or holding the medium in an atmosphere containing Ar and, in addition, a small amount of oxygen or other gases. The atmosphere in which the magnetic recording medium is held may be not only a vacuum but also a pressured atmosphere of 1 atm or more. The latter can be achieved by appropriately setting conditions for the species and partial pressures of gases in the atmosphere in which the medium is held, a pressure under which the medium is held, and a time.

An ion gun may be used to etch the memory layer made of TbFeCo, thereby causing the memory layer to contain hydrogen. Alternatively, sputtering gas of Ne, Ar, Kr, Xe or others may be used to perform dry etching, such as ion irradiation etching or plasma etching, with respect to the memory layer.

After formation of the memory layer or other thin layers, the resistivity of the memory layer can be increased by an etching step. The etching power and the species of ion gas for irradiation may be changed.

The recording layer may be fabricated by introducing Ar gas into a vacuum process chamber which is evacuated to a high vacuum of 7*10⁻⁶ Pa or less, or sputtering gas may be introduced into a vacuum process chamber having a vacuum degree of 5*10⁻⁵ Pa or less which is reached before formation of the memory layer so as to grow the memory layer. In either case, the same effect is obtained.

During formation of the memory layer made of TbFeCo, by controlling the film formation rate and the rotational speed of the disk substrate, microstructures of films of Tb, and Fe and Co can be changed, so that a magnetic thin layer having an amorphous film structure having a large magnetic anisotropy may be used. More specifically, during formation of the TbFeCo memory layer, the respective element particles are each deposited at a film formation rate of 0.5 nm/sec while the disk substrate is being rotated and revolved at 40 rpm, thereby making it possible to obtain the above-described film structure.

It has been described above that the memory layer has a multilayer structure using magnetically induced super-resolution. A similar effect is obtained if the memory layer can hold recorded information. A single-layer structure may be used, or alternatively, a two-layer structure may be used in which a readout layer and a memory layer for increasing the signal amount of reproduced information are provided and mutually magnetically exchange-coupled.

The memory layer may be a magnetic thin layer made of a rare earth metal-transition metal alloy containing at least one of rare earth metal materials, such as Tb, Gd, Dy, Nd, Ho, Pr, and Er, and a transition metal(s), such as Fe, Co, and Ni. In this case, the rare earth metal is preferably contained in the memory layer in an amount of 15 at % to 28 at %.

The readout layer may be a single-layer or multilayer structure made of GdFeCoCr, GdFeCoAl, or other material compositions.

During formation of the memory layer of TbFeCo, by controlling the film formation rate and the rotational speed of the disk substrate, Tb, and Fe and Co (transition metals) may be laminated in a periodic structure. In this case, if the laminated structure is caused to have a lamination cycle of at least 2.0 nm or less, the product Ms·Hc of the saturated magnetization Ms and the coercive force Hc of the memory layer can be increased. Actually, when the memory layer has a lamination cycle of 1.0 nm, an Ms·Hc value of as large as 4.0*10⁶ erg/cm³ is obtained. Even when a small magnetic domain of 50 nm or less is recorded, a stable recorded magnetic domain can be formed. Also, even when recording and reproduction are repeatedly performed, it is possible to achieve recording and reproduction with excellent signal characteristics.

The memory layer may have a laminated structure in which Tb and FeCo are laminated in lamination cycles of 0.3 nm or more and 4 nm or less. The memory layer may have a film thickness of about 10 nm to 400 nm, 20 nm or more, and more preferably 40 nm to 200 nm. The present invention is not limited to the periodic laminated structure of Tb, and Fe and Co (transition metals). Alternatively, different targets of Tb, Fe, and Co, or other materials may be used as long as the memory layer has a structure having a lamination cycle of 2 nm or less.

The Curie temperature of the memory layer may be set within a temperature range of at least 150° C. or more, depending on characteristics of a magnetic head, conditions for an increase in temperature by an optical head, and the tolerable range of ambient temperature.

A change in magnetic characteristics of the magnetic recording medium depends on a change in the disk substrate or the underlying layer. If coercive force, saturated magnetization, magnetic flux density, magnetic anisotropy, or their temperature characteristics, or the like of the memory layer of the present invention is adjusted, the same or higher level of effect is obtained.

The magnetic disk employing magnetically induced super-resolution by DWDD has been described above. It has been described above that the film structure includes a readout layer, an intermediate layer, and a memory layer, or further a control layer. The present invention is not limited to this structure. The magnetic recording medium may have a film structure in which a transferred magnetic domain is expanded and reproduced by a magnetically induced super-resolution technique, such as RAD, FAD, CAD, and a double-mask method, or MAMMMOS or the like. Also, the structure of the recording film is not limited to the three-layer structure including a memory layer, an intermediate layer, and a readout layer, and may be a multilayer structure which has a required function. Note that, in the case of a multilayer structure, the memory layer and the readout layer preferably have different magnetic domain wall energy densities. When an intermediate layer is further provided, the magnetic domain wall energy density of the intermediate layer is preferably larger than that of the readout layer. The magnetic anisotropy in the out-of-plane direction of the intermediate layer is preferably larger than that of the readout layer at about room temperature. The magnetic domain wall energy of the readout layer preferably differs between in the in-plane direction and in the out-of-plane direction. The magnetic domain wall coercive force of the readout layer is preferably smaller than those of the memory layer and the intermediate layer. The magnetic domain wall width in the in-plane direction of the intermediate layer is preferably smaller than the magnetic domain wall width of the readout layer or the magnetic domain wall width in the out-of-plane direction of the intermediate layer. Thereby, a magnetic domain is likely to be formed in a transfer direction from the memory layer, so that a small magnetic domain formed in the memory layer can be easily transferred to the readout layer. The magnetic domain wall width in the depth direction of the intermediate layer is preferably smaller than the film thickness thereof.

Thereby, a magnetic domain wall is generated in the film thickness direction of the readout layer, which isolates the memory layer and the readout layer, so that the magnetic domain wall can be smoothly displaced (DWDD operation).

It has been described above that the magnetic recording medium employing DWDD includes a disk substrate in which concaves and convexes or pits having different surface roughnesses are formed. Alternatively, grooves or lands may be provided and recording tracks may be separated from each other. Alternatively, a guide groove may be provided between tracks, and annealing may be performed. With such a structure, tracks in which information is recorded are magnetically isolated from each other, so that a recorded magnetic domain transferred to the readout layer can facilitate magnetic domain wall displacement, resulting in more excellent signal characteristics in DWDD. Thus, by separating recording tracks using concaves and convexes (grooves or lands), a small magnetic domain of 0.1 μm or less can be stably formed, and the mobility of a magnetic domain wall of transferred magnetic domains by DWDD can be secured, resulting in a magnetic disk having excellent reproduced signal characteristics. Further, crosswrite and crosstalk from adjacent tracks can be reduced during recording and reproduction.

Note that the disk substrate can be formed of glass, an Al alloy metal, polycarbonate, other metal materials, a plastic material, or the like.

Also, the disk substrate may have any of various structures formed by: forming pits in a surface thereof using a photopolymer; imprinting or the like; processing using direct etching; forming pits by directly processing the disk substrate or by heating and melting glass and transferring the melted glass to the disk substrate; and transferring to a photopolymer by imprinting or the like. The disk substrate employing surface roughness can be formed by using a stamper which is fabricated by directly processing a photoresist master plate by etching to transfer to the disk substrate, or by directly etching an underlying surface formed on the disk substrate.

Even when a memory layer is formed on a disk substrate on which self-organized organic small particles are applied, recording can be performed in high density corresponding to the size of a pattern of the small particles. If the small particles have uniform characteristics and a small diameter, recording can be performed in higher density. Alternatively, a pattern of self-organized small particles may be transferred to a disk substrate. Particularly, the same effect is obtained by performing etching or the like after small particles are applied or transferred.

The track pitch may be such that a groove in which information is recorded has a width of 0.6 μm or less, and a recorded domain in which the shortest mark length of recorded information is 0.3 μm or less is recorded. It is more advantageous that the recording track and the linear recording density are reduced.

The pit preferably has a depth within the range of 10 nm to 200 nm, though the depth and size are not limited. If a signal from a pit, such as a servo pit or an address pit, is detectable using a magnetic head and the pit is as small as possible, the same or higher level of effect can be obtained.

An address can be detected by pits having different surface shapes, magnetically recorded pits, grooves, or wobbled lands. In this case, only one side of the groove or the land can be wobbled.

A heat absorbing layer having a large thermal conductivity and a layer having a small thermal conductivity may be formed between the disk substrate and the underlying dielectric layer so as to control a temperature distribution and heat conduction in the disk.

Examples of the underlying layer on the disk substrate include SiN, AlTiN, ZnSSiO₂, TaO, AgCu, AlTi, and AlCr, oxides or nitrides of Cr, Ti, Ta or other elements, II-VI compounds and III-V compounds such as chalcogen compounds, metals such as Al, Cu, Ag, Au, and Pt, and a mixture material thereof.

These materials may be used as a material for the protective layer.

When the DLC layer formed as the protective layer can be formed more densely by chemical vapor deposition or the like.

It has been described above that the protective layer is formed of amorphous carbon by sputtering. The present invention is not limited to this, as long as the protective layer is formed of a material which has a small surface roughness Ra, a small friction coefficient, and a large film strength.

Alternatively, the protective layer may be formed by applying an epoxy-acrylic resin or an urethane resin in a uniform film thickness of about 5 μm by spin coating, and curing the resin by irradiation with a UV lamp or thermally.

The lubricating protective layer made of a perfluoropolyether can be formed by spin coating, dipping, or the like. The lubricating layer may be formed of any material that is stable on the underlying protective layer.

A tape-burnishing treatment may be added to the formation of the magnetic recording medium so as to remove foreign matter, protrusions, or the like without damaging a surface thereof, thereby providing an application step with which satisfactory evenness is obtained with a uniform film thickness from the inner periphery to the outer periphery.

The disk substrate may be of a double-sided type. In this case, servo pits need to be formed on both sides of the disk substrate, and a recording layer and a protective layer also need to be formed on both sides of the disk substrate. Further, a recording and reproducing apparatus is required to have a drive structure in which magnetic heads are attached to face both sides of the recording film.

In the magnetic recording medium of the present invention, the memory layer is provided on the disk substrate at least in the out-of-plane direction. The memory layer has a structure in which the memory layer is separated into magnetic grains and recorded domains are magnetically isolated, or a structure in which small structures which are each an aggregate of mutually isolated magnetic grains are formed in the recording film, and the recording film has a large specific resistance. Thereby, a small recorded magnetic domain can be stably recorded, and recording density can be significantly increased without deteriorating the amplitude of a reproduced signal. Also in a recording medium in which magnetic recording and reproduction are performed while the temperature of the recording film is increased by irradiation with light, servo characteristics can be stabilized, thereby improving reliability, leading to higher productivity of the disk and a significant reduction in cost.

Further, it is possible to provide a magnetic recording medium in which, even when rewriting is repeatedly performed in high density, stable recording and reproduction characteristics are obtained, and excellent signal characteristics are obtained, a production method thereof, and a recording and reproducing method thereof.

### INDUSTRIAL APPLICABILITY

The magnetic recording medium of the present invention enables high-density recording of information, and is useful as and applicable to an information storage device and a memory medium including a hard disk.

### BRIEF DESCRIPTION OF DRAWINGS

FIG. 1 is a cross-sectional view showing a structure of a magnetic recording medium according to an embodiment of the present invention.

FIG. 2A is a characteristic diagram showing a cross-section of the magnetic recording medium of the embodiment of the present invention observed by an SEM. FIG. 2B is a characteristic diagram showing a cross-section of a conventional magnetic recording medium observed by an SEM.

FIG. 3 is a cross-sectional view showing a structure of a magnetic recording medium according to Embodiment 2 of the present invention.

FIG. 4 is a cross-sectional view showing a structure of a magnetic recording medium according to Embodiment 3 of the present invention.

FIG. 5 is a characteristic diagram showing a relationship between the resistivity of a thin memory layer of the magnetic recording medium of the embodiment of the present invention and a gas pressure during formation of the memory layer.

FIG. 6 is a cross-sectional view showing a structure of a magnetic recording medium according to Embodiment 5 of the present invention.

FIG. 7 is a characteristic diagram showing a cross-section of the magnetic recording medium of Embodiment 5 of the present invention observed by an SEM.

FIG. 8 is a characteristic diagram showing a relationship between the resistivity of a thin memory layer of the magnetic recording medium of the embodiment of the present invention and an etching time for the memory layer.

FIG. 9 is a diagram showing a configuration of a production apparatus for producing the magnetic recording medium of the embodiment of the present invention.

FIG. 10 is a diagram showing a configuration of a recording and reproducing apparatus for the magnetic recording medium of the embodiment of the present invention.

FIG. 11A, 11B, 11C, and 11D are diagrams for explaining the reproduction principle of DWDD.

FIG. 12 is a characteristic diagram showing a distribution of molar ratios, a distribution of saturated magnetization, a distribution of magnetic anisotropies, and a distribution of magnetic domain wall energy densities in an in-plane direction of a magnetic recording film in the magnetic recording medium of the embodiment of the present invention.

FIG. 13 is a graph showing a relationship between the Tb content and the coercive force of the magnetic recording film in the magnetic recording medium of the embodiment of the present invention.

FIG. 14 is a graph showing a relationship between the temperature and the coercive force of the magnetic recording film in the magnetic recording medium of the embodiment of the present invention.

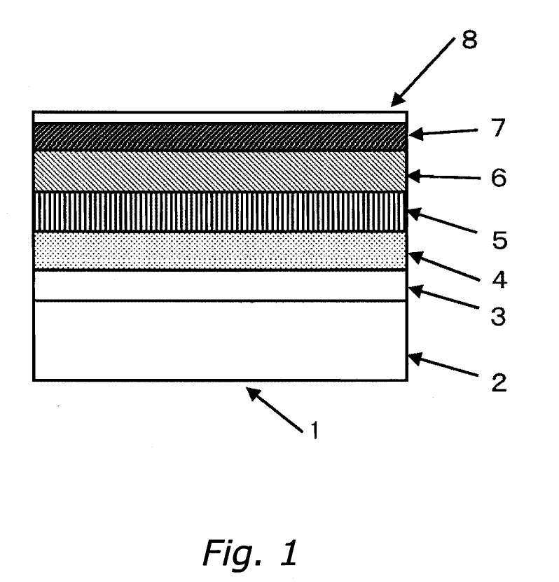

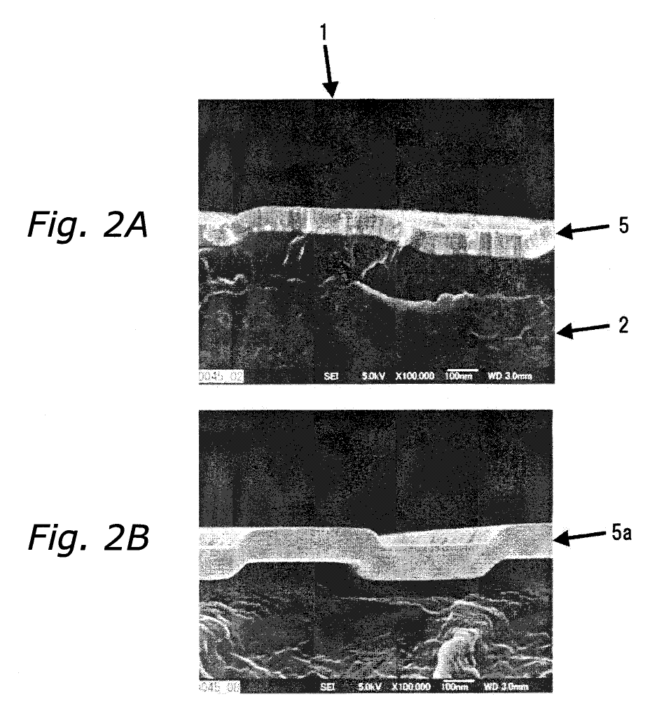

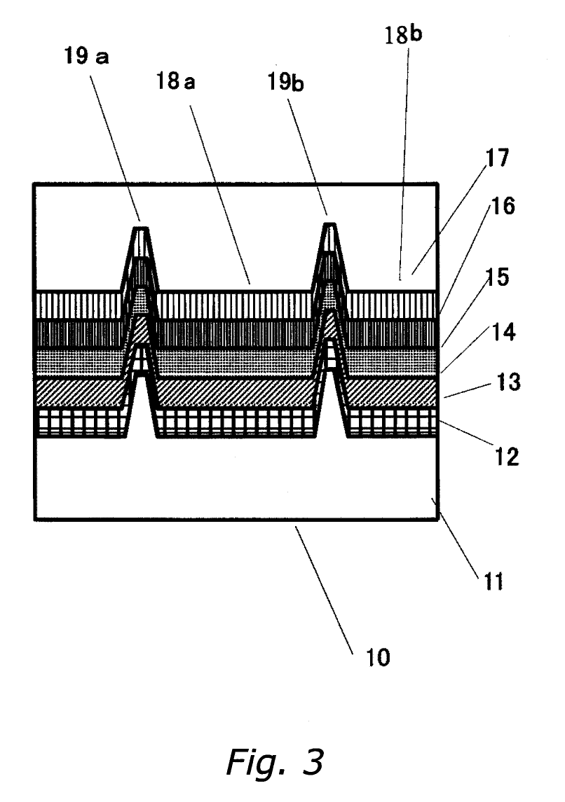

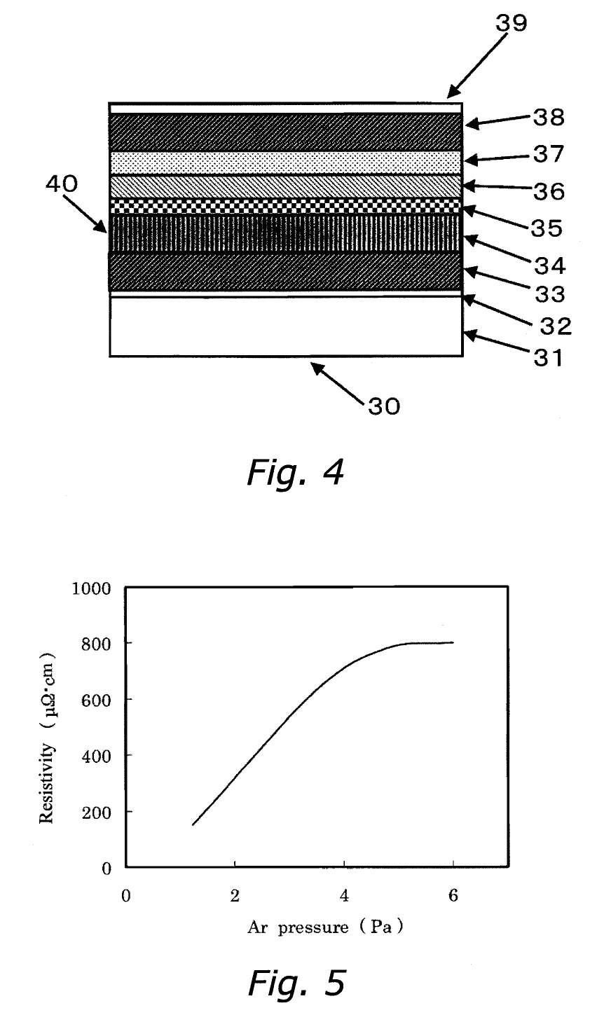

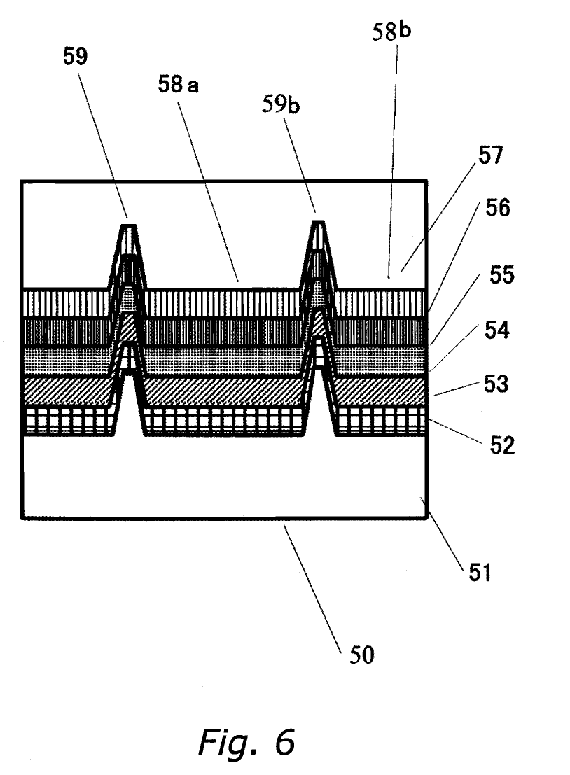

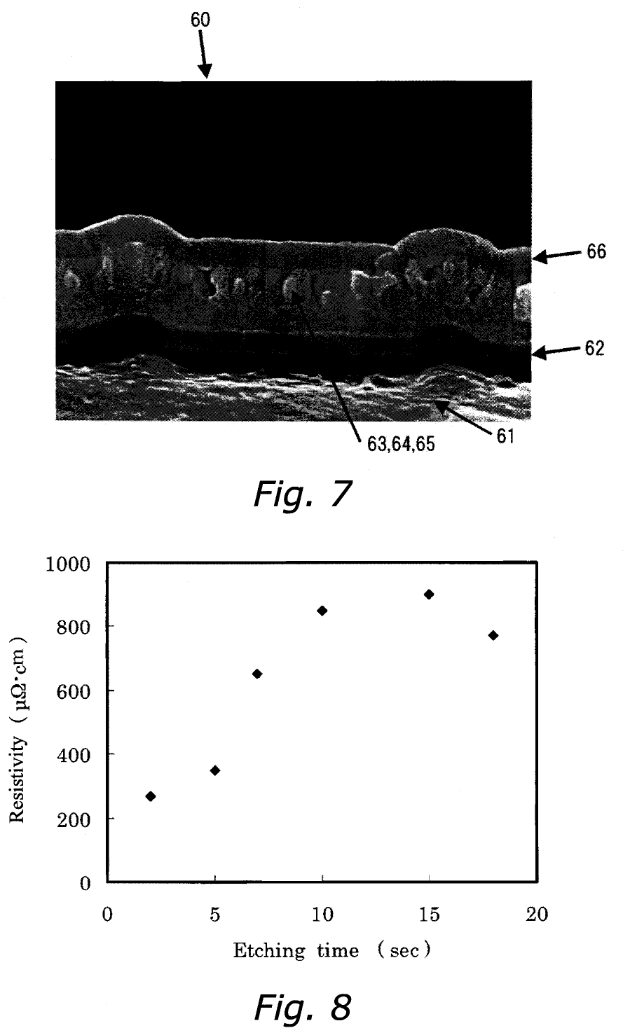

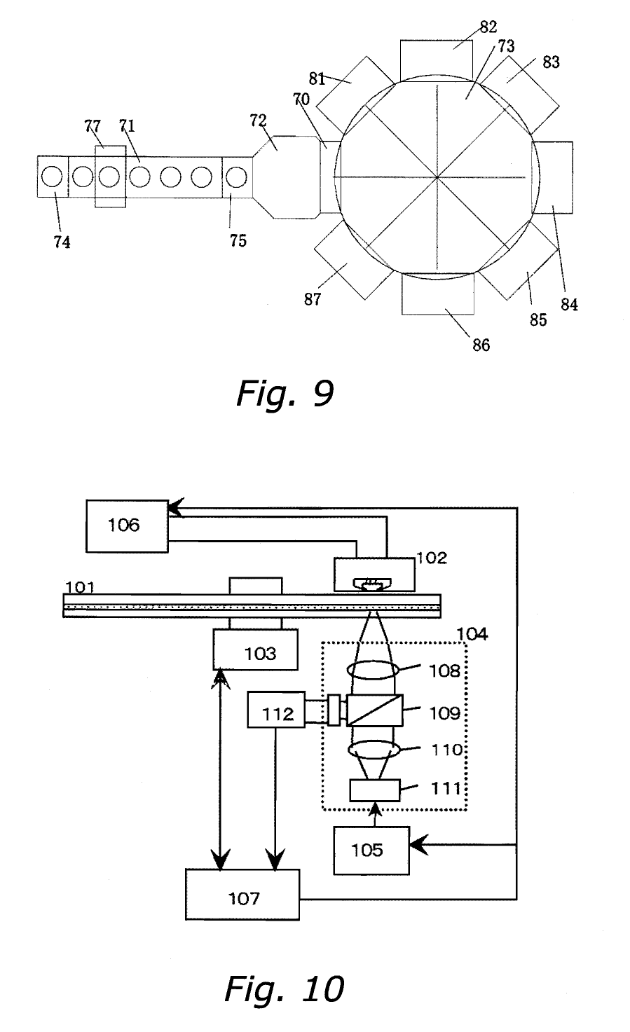

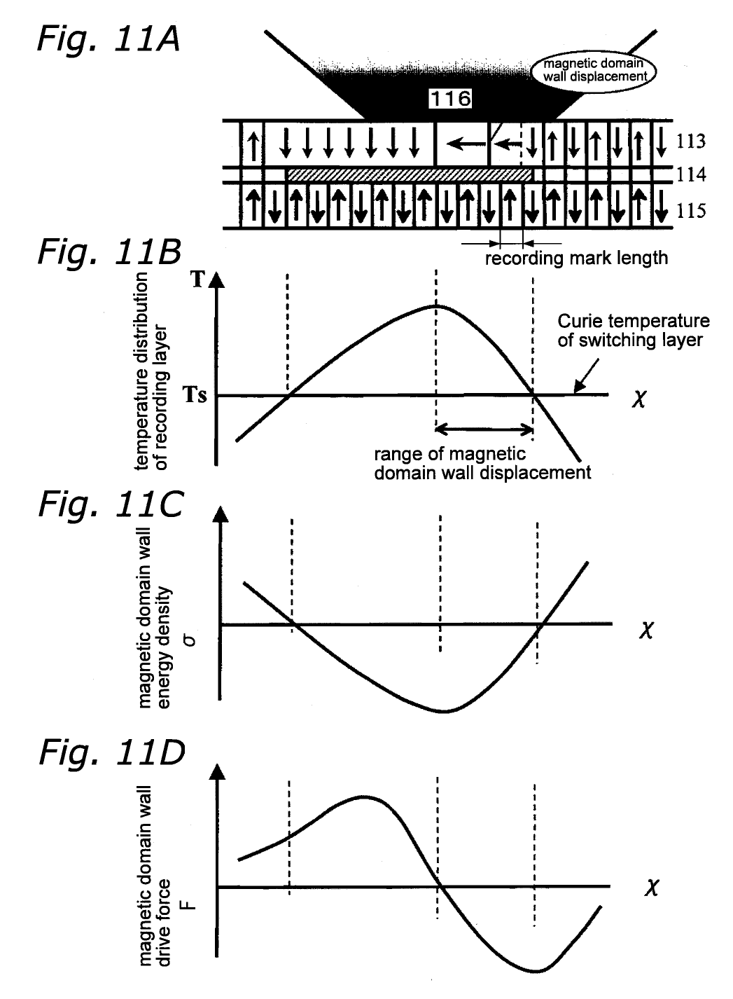

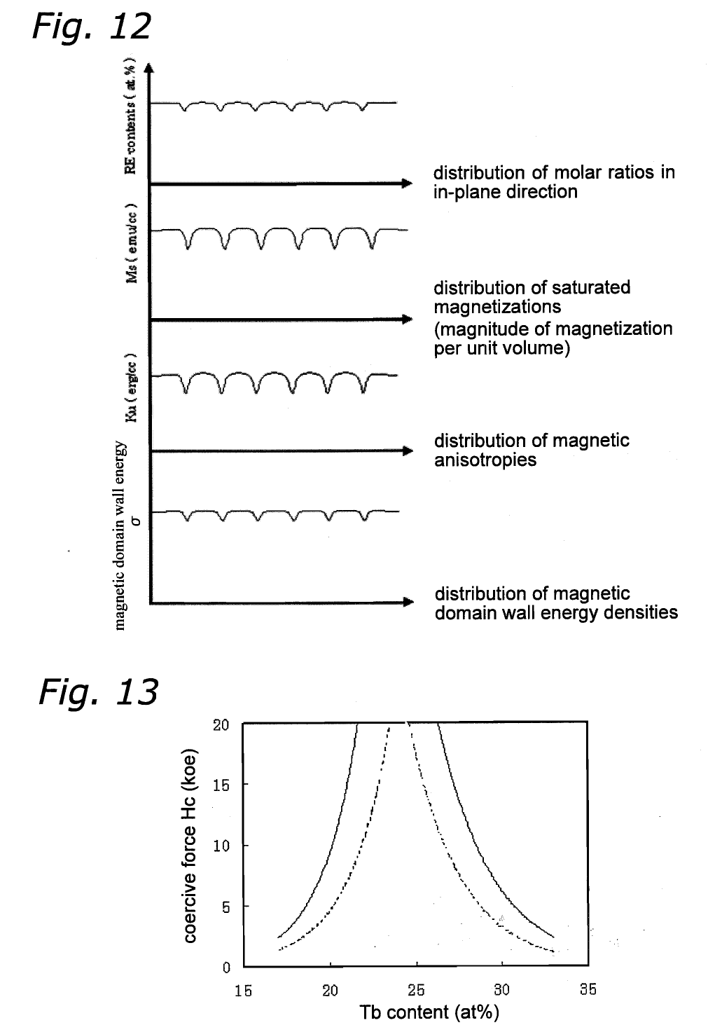

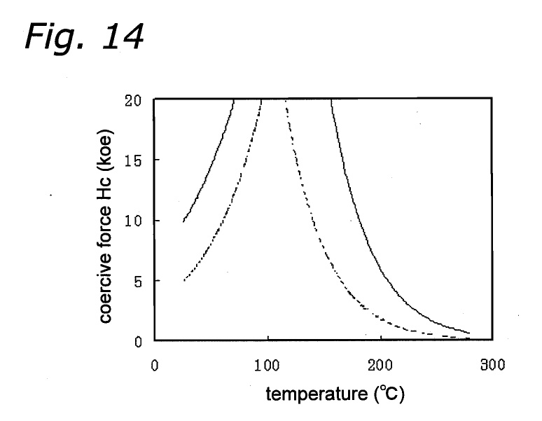

### EXPLANATION OF REFERENCE

1, 10, 30, 50 magnetic disk
2, 11, 31, 51 disk substrate
3, 12, 33, 52 dielectric layer
4 underlying magnetic layer
5, 13, 34, 53 memory layer
14, 35, 54 intermediate layer
15, 37, 55 readout layer
6, 16, 38, 56 dielectric layer
7, 17, 39, 57 lubricating layer
8 texture treatment
32 photopolymer
36 control layer
101 magnetic disk
102 magnetic head
103 spindle motor
104 optical head

1-34. (canceled)

35. A magnetic recording medium comprising a magnetic recording film including a memory layer made of an amorphous material having magnetic anisotropy at least in an out-of-plane direction on a disk substrate, wherein at least the memory layer is an aggregate of mutually magnetically isolated magnetic grains, and the memory layer has a density periodically varying in an in-plane direction depending on the width of the magnetic grain, or the memory layer contains, in border regions between the magnetic grains in the in-plane direction, at least one element selected from the group consisting of hydrogen and inert gaseous elements, so that the memory layer has a uniform composition except for the element, but has a composition containing hydrogen or the inert gaseous elements periodically varying in the in-plane direction depending on the width of the magnetic grain.

36. The magnetic recording medium according to claim 35, wherein the magnetic grain has a width of 2 nm to 50 nm as a structural unit.

37. A magnetic recording medium comprising a magnetic recording film including a memory layer made of an amorphous material having magnetic anisotropy at least in an out-of-plane direction on a disk substrate, wherein at least the memory layer has a density periodically varying in an in-plane direction, or the memory layer contains at least one element selected from the group consisting of hydrogen and inert gaseous elements, so that the memory layer has a uniform composition except for the element, but has a composition containing hydrogen or the inert gaseous elements periodically varying in the in-plane direction.

38. The magnetic recording medium according to claim 37, wherein the magnetic grains are mutually magnetically isolated in the memory layer.

39. The magnetic recording medium according to claim 37, wherein a modulation cycle of the composition or density in the in-plane direction is smaller than a film thickness of the memory layer.

40. The magnetic recording medium according to claim 35, wherein the memory layer includes magnetic grains forming recorded magnetic domains and border regions between the magnetic grains.

41. The magnetic recording medium according to claim 35, wherein the border region has a coercive force or magnetic domain wall energy density smaller than that of the magnetic grain.

42. The magnetic recording medium according to claim 35, wherein a width in the in-plane direction of the border region is smaller than a film thickness of the memory layer.

43. The magnetic recording medium according to claim 35, wherein a resistivity in the in-plane direction of the memory layer is 500 μΩcm or more.

44. The magnetic recording medium according to claim 35, wherein the magnetic grains in the memory layer are column-shaped structures which are mutually magnetically isolated.

45. The magnetic recording medium according to claim 35, wherein the memory layer is separated to form the mutually magnetically isolated magnetic grains by interface regions thereof in first cycles which are the same as changes of a surface shape of an underlying layer or in second cycles, each of which is an integral multiple of the first cycle.

46. The magnetic recording medium according to claim 35, wherein the inert gaseous element is at least one selected from He, Ne, Ar, Kr, and Xe.

47. The magnetic recording medium according to claim 35, wherein the memory layer contains a rare earth metal.

48. The magnetic recording medium according to claim 47, wherein the rare earth metal is at least one of Tb, Gd, and Dy.

49. The magnetic recording medium according to claim 47, wherein the rare earth metal is contained in the memory layer in an amount of 15 at % to 28 at %.

50. The magnetic recording medium according to claim 35, wherein the memory layer has a film thickness of 10 nm to 400 nm.

51. The magnetic recording medium according to claim 35, wherein the magnetic recording film includes a readout layer magnetically coupled with the memory layer.

52. The magnetic recording medium according to claim 51, wherein the memory layer and the readout layer have different magnetic domain wall energy densities.

53. The magnetic recording medium according to claim 51, wherein the magnetic recording film further includes an intermediate layer, and the intermediate layer has a larger magnetic domain wall energy density than that of the readout layer.

54. The magnetic recording medium according to claim 53, wherein the intermediate layer has a larger magnetic anisotropy in an out-of-plane direction than that of the readout layer at room temperature.

55. The magnetic recording medium according to claim 51, wherein the readout layer has magnetic domain wall energy differing between in an in-plane direction and in an out-of-plane direction.

56. The magnetic recording medium according to claim 51, wherein the readout layer has a smaller magnetic domain wall coercive force than that of the memory layer and the intermediate layer.

57. The magnetic recording medium according to claim 51, wherein a magnetic domain wall width in an in-plane direction of the intermediate layer is smaller than a magnetic domain wall width of the readout layer or a magnetic domain wall width in an out-of-plane direction of the intermediate layer.

58. The magnetic recording medium according to claim 51, wherein a magnetic domain wall width in a depth direction of the intermediate layer is smaller than a film thickness thereof.

59. The magnetic recording medium according to claim 35, wherein the disk substrate has concaves and convexes in a surface thereof.

60. The magnetic recording medium according to claim 35, wherein concaves and convexes are formed in a surface which the memory layer contacts.

61. A method for producing a magnetic recording medium comprising a magnetic recording film including a memory layer made of an amorphous material having magnetic anisotropy at least in an out-of-plane direction on a disk substrate, the memory layer has a density periodically varying in an in-plane direction, or the memory layer contains at least one element selected from the group consisting of hydrogen and inert gaseous elements, so that the memory layer has a uniform composition except for the element, but has a composition containing hydrogen or the inert gaseous elements periodically varying in the in-plane direction, wherein the memory layer is formed on a layer having a surface roughness of 0.5 nm or more by sputtering in an atmosphere containing at least one of Ne, Ar, Kr, and Xe.

62. A method for producing a magnetic recording medium comprising a magnetic recording film including a memory layer made of an amorphous material having magnetic anisotropy at least in an out-of-plane direction on a disk substrate, the memory layer has a density periodically varying in an in-plane direction, or the memory layer contains at least one element selected from the group consisting of hydrogen and inert gaseous elements, so that the memory layer has a uniform composition except for the element, but has a composition containing hydrogen or the inert gaseous elements periodically varying in the in-plane direction, wherein the memory layer is formed in a vacuum atmosphere by controlling conditions for formation of the layer so that the energy density of an element included in the memory layer is 1 A/mm² or less.

63. A method for producing a magnetic recording medium comprising a magnetic recording film including a memory layer made of an amorphous material having magnetic anisotropy at least in an out-of-plane direction on a disk substrate, the memory layer has a density periodically varying in an in-plane direction, or the memory layer contains at least one element selected from the group consisting of hydrogen and inert gaseous elements, and the memory layer has a uniform composition except for the element, but has a composition containing hydrogen or the inert gaseous elements periodically varying in the in-plane direction, wherein the memory layer is formed in a vacuum atmosphere by controlling conditions for formation of the layer so that a power applied to an element included in the memory layer is 300 W or less.

64. A method for producing a magnetic recording medium comprising a magnetic recording film including a memory layer made of an amorphous material having magnetic anisotropy at least in an out-of-plane direction on a disk substrate, the memory layer has a density periodically varying in an in-plane direction, or the memory layer contains at least one element selected from the group consisting of hydrogen and inert gaseous elements, so that the memory layer has a uniform composition except for the element, but has a composition containing hydrogen or the inert gaseous elements periodically varying in the in-plane direction, wherein the memory layer is formed at a pressure of 2 Pa or more.

65. A recording and reproducing method for the magnetic recording medium according to claim 35, wherein an information signal is recorded to or reproduced from the magnetic recording medium while increasing the temperature of the memory layer by irradiating the magnetic recording medium with a laser spot.

66. A recording and reproducing method for the magnetic recording medium according to claim 35, wherein an information signal is recorded to or reproduced from the magnetic recording medium using a magnetic head.
